(19) United States
(12) Patent Application Publication
(10) Pub. No.: US 2025/0046682 A1
(43) Pub. Date: Feb. 6, 2025

(54) SEMICONDUCTOR POWER ENTITY, METHOD FOR PRODUCING SUCH ENTITY BY HYBRID BONDING AND HYBRID BOND SHEET

(71) Applicant: Huawei Digital Power Technologies Co., Ltd., Shenzhen (CN)

(72) Inventors: Andreas MUNDING, Nuremberg (DE); Lasse Petteri Palm, Nuremberg (DE); Yumin Liu, Shanghai (CN)

(73) Assignee: Huawei Digital Power Technologies Co.,Ltd., Shenzhen (CN)

(21) Appl. No.: 18/885,912

(22) Filed: Sep. 16, 2024

Related U.S. Application Data
(63) Continuation of application No. PCT/CN2022/136786, filed on Dec. 6, 2022.

(30) Foreign Application Priority Data
Mar. 22, 2022 (WO) PCT/EP2022/057389

(51) Int. Cl. H01L 23/488; H01L 23/00; H01L 23/31; H01L 25/00; H01L 25/10

(52) U.S. Cl. CPC H01L 23/488; H01L 23/3107; H01L 24/24; H01L 25/105; H01L 25/50; H01L 2224/24145; H01L 2225/1058

(57) ABSTRACT

A hybrid bond sheet for bonding a first joining member to a second joining member, including: a core layer including: a core insulating layer formed between an upper main face and a lower main face of the core layer; and one or more metallic through-connections penetrating the core insulating layer from the upper main face to the lower main face. The hybrid bond sheet includes a first bonding layer with a first insulating bond layer and a first metal bond layer for bonding the first joining member. The hybrid bond sheet includes a second bonding layer with a second insulating bond layer and a second metal bond layer for bonding the second joining member. The one or more metallic through-connections and the first and second metal bond layers are configured to form an electrically and thermally conductive connection with the first joining member and the second joining member.

### CROSS-REFERENCE TO RELATED APPLICATION

This application a continuation of International Patent Application No. PCT/CN2022/136786, filed on Dec. 6, 2022, the disclosure of which is hereby incorporated by reference in its entirety.

### TECHNICAL FIELD

In the field of power products and production methods thereof, the embodiments relate to a semiconductor power entity, a method for producing such entity by hybrid bonding, a hybrid bond sheet, and a hybrid bonding method and a corresponding structure.

### BACKGROUND

In order to increase power density and efficiency in next generation power packages, short, current-capable low-parasitic interconnection paths, a very good thermal management and electrical isolation are essential. Conductor traces with a current capability of several ten amperes up to hundreds of amperes, and power modules with an internal stray inductance of a new nH or below are the current targets.

In today's chip embedding technology, only limited interconnect capabilities are available. For making connections between two vertically arranged power semiconductors on 2 different core layers, only micro-via interconnects are possible that are produced outside of both component's projected physical outline, i.e., outside of the die area. The through-via has to be placed in a minimum distance of about 400 to 500 μm from the embedded component edge in order to account for via process tolerances. This leads to a long routing distance and results in a high commutation loop inductance. Another severe disadvantage of this arrangement is the thermal decoupling by the usually low thermally conductive laminate layer between the two dies. Depending on the cooling situation on either side of the assembly, the dies could reach different operating temperature and develop a dispersive switching behavior.

### SUMMARY

The embodiments provide a solution for semiconductor power products and manufacturing such power products without the above-described disadvantages.

The embodiments include a solution for a semiconductor power entity that has improved thermal characteristics and provides low parasitic interconnection paths. The embodiments also include a hybrid bond sheet for bonding two joining members that has improved thermal characteristics and can be advantageously applied in the above semiconductor power entity.

The solution presented in the embodiments achieves these objects at a reasonable cost by the combination of vertical system integration (3^{rd} dimension integration, 3D-integration), panel level packaging, and low temperature metal joining (e. g. diffusion soldering or sintering). By the combination of these technologies, the following advantages can be realized:

Vertical system integration (3^{rd} dimension integration, 3D-integration) drastically shortens interconnect length and allows to significantly increase the power density. According to the embodiments, this technology can be used in an industrialized scale for chip embedding or other panel level packaging technologies and for power device packaging.

Hybrid bonding according to the embodiments is a process that allows simultaneously bonding of metallic contacts & dielectric areas in one bonding process. Hybrid bonding can be used for 3D-integration on a wafer level. In some embodiments, a direct surface activated bonding (SAB) process is used, which may require specialized high vacuum equipment and tight control of surface quality with a roughness in the range of about 1 nm, for example. This makes hybrid bonding in its current form unsuitable for power electronics packaging. The embodiments provide a mechanism to make this technology available for panel level hybrid bonding process for power electronics packaging.

Chip embedding (CE) according to the embodiments employs PCB (printed circuit board) materials interfacing directly with the semiconductor die. In addition to excellent electrical and thermal performance, chip embedding offers the benefits of panel scale mass production. Currently, CE, which is still new technology, is not yet used for 3D stacking. It could be used but due to limitations, e.g., direct vertical connections, it is not yet used (only one core layer, i.e., laminate layer).

According to the embodiments, vertical connections can be implemented between pre-manufactured printed circuit board (PCB) layers, resulting in a connection layer that embeds large connection metal areas in isolation material, achieving sufficient current carrying capability and thermal conductivity for power electronics.

The embodiments are based on the concept where direct vertical connections can be made between two or more laminate core layers, also referred to as laminate layers or core layers, where the vertical connections have the following characteristics: they can be made within the projected physical outline of embedded components; they are not confined to a certain shape (e. g. round) or size (e. g. 100 μm diameter); they do not need an outer layer plating process to form the electrical connection; they are suitable for power electronics (have low inductance and high current capability); they are reliable and do not remelt at bond temperature; they can be formed by diffusion soldering, sintering, or nanowired Velcro welding or Velcro sintering.

A method or process to form these vertical connections has the following characteristics: using a standard PCB lamination process (bond temperature, pressure, format); using hybrid bonding to bond metal to metal and dielectric to dielectric in one step; several premanufactured layers can be connected to each other in one lamination step or in several sequential lamination steps; the bonding materials can be attached or applied to the surface of the laminate layers or placed between the laminate layers prior to bonding.

Alternatively, the bond materials can be supplied in form of a premanufactured hybrid bond sheet with vertical connections and pre-dried or B-staged bond materials at the top and bottom surface. The contact areas on the bond sheet can have a regular uniform repetitive pattern that fits many application purposes or can be designed to suit the interconnection demand of a particular product.

A hybrid bond sheet as presented in the embodiments can be applied for the hybrid bonding of metal to metal and dielectric to dielectric in one step.

In case of diffusion soldering, the vertical metal-to-metal connection can be based on the formation of intermetallic phases in a selected bi- or multi metal system. The structure can have a minimum of three layers that contain at least one metal or metal alloy layer that has a low melting point and which is located between two separate metal layers that have a high melting point.

Low melting point metals that can be used are, e.g., tin (Sn) and indium (In), and the high melting point metal or top metal layers are, e.g., copper (Cu), gold (Au) and silver (Ag). In diffusion soldering, the two high melting point metal layers can be bonded together by aim of at least one low temperature melting metal layer. During the bonding the layer can be pressed against each other and the temperature can be increased above the eutectic point for the selected metal system. Because the temperature is above the eutectic point of the selected metal system, a liquid phase can appear and the metals can start to inter-diffuse and create intermetallic compounds (IMCs). Because the formed inter-metallics have a higher melting point, those are gradually solidified. If the bonding time is long enough, all low melting point metals react with the high melting point metals to form inter-metallics and the joint is completely solidified. The formed intermetallic compounds have a significantly higher melting point than the low melting point metals and the joint does not melt anymore at the bonding temperature.

The diffusion soldering process can be divided into five phases that are wetting, alloying, liquid diffusion, gradual solidification, and solid diffusion. The suitable metal, metal alloy, or paste, on one or both laminate layers, or between the laminate layers (with metal), can be applied by plating, printing, dispensing, or other suitable methods. Diffusion soldering or sintering can be used, for example, to form the metallic interconnection.

The semiconductor power entity can be described by the following main features, that are: two or more laminate layers that i) are laminated together with isolating polymer layer; ii) have Cu metal routing at least on top and bottom side; iii) are electrically connected together with a non-remeltable metal joint embedded in the isolating polymer layer.

Other features are as follows: all laminate layers are PCB core layer in panel level (up to normal PCB production sizes); the bond material can be applied in different ways: on the surface of the joining members or as a bond sheet which is placed in between the laminate layers during stack-up; at least one laminate layer has power components embedded inside; the first power die in the first laminate layer and the second power die in the second laminate layer can face in different directions, but are not limited to this, in some other applications they can also face in the same direction. In one example, the first power die in the first laminate layer and the second power die in the second laminate layer can be arranged in a half bridge configuration. It can be understood that many other configurations of the two power dies can be implemented as well.

In order to describe the embodiments in detail, the following terms, abbreviations and notations will be used:
PCB printed circuit board
SAB surface activated bonding
HDI high density interconnect
SLID solid liquid interdiffusion
TLP transient liquid phase
TLPB transient liquid phase bonding
IMC intermetallic compound

The embodiments relate to a semiconductor power entity according to a first aspect, a method for producing such semiconductor power entity according to a second aspect, a computer program product according to a third aspect, and a non-transitory computer-readable medium according to a fourth aspect, as described in the following.

According to the first aspect, the embodiments relate to a semiconductor power entity, including: a first laminate layer having a first laminate upper main face and a first laminate lower main face opposing the first laminate upper main face; a second laminate layer having a second laminate upper main face and a second laminate lower main face opposing the second laminate upper main face; an isolation layer arranged between the first laminate layer and the second laminate layer; a first metal layer arranged at the first laminate upper main face of the first laminate layer and a second metal layer arranged at the first laminate lower main face of the first laminate layer; a third metal layer arranged at the second laminate upper main face of the second laminate layer and a fourth metal layer arranged at the second laminate lower main face of the second laminate layer; and a connection metal layer embedded in the isolation layer between the first laminate layer and the second laminate layer, the connection metal layer forming an electrical connection with the second metal layer and the third metal layer.

Such a semiconductor power entity provides at least the advantage of having direct vertical connections between two or more laminate core layers. These vertical connections can be made within the projected physical outline of embedded components if the laminate layer have such embedded components; they are not confined to a certain shape or size, i.e., they can be flexible designed in shape and size; they do not need an outer layer plating process to form the electrical connection; they are suitable for power electronics, since they have low inductance and high current capability; they are reliable and do not remelt at bond temperature. These vertical connections can be formed, for example by solid-liquid interdiffusion (SLID), transient liquid phase (TLP) bonding or sintering.

Thus, the semiconductor power entity provides increased power density and efficiency, short, current-capable low-parasitic interconnection paths, a very good thermal management, and improved electrical isolation. Conductor traces with a current capability of several ten amperes up to hundreds of amperes and even higher, and power modules with an internal stray inductance of a few nH or below can be achieved.

The first, second, third and fourth metal layers can be redistribution or routing metal layers for redistributing or routing current paths. It can be understood that the semiconductor power entity is not restricted to these four metal layers and two laminate layers as exemplarily shown in the Figures. The semiconductor power entity can also have more layers. The layers that are laminated may also be the layers of a multi-layer board, e.g., four layers or six layers, instead of the two-layer boards that are shown here in the Figures which are only examples for such a multi-layer board.

The semiconductor power entity can also be referred to as semiconductor power product. Such a product can also be a module or a larger size product (PCB), for example, where the power components may be embedded inside the PCB and the rest of the components may be placed on top. Some or all of the passives may also be embedded in the PCB, depending on the passive components, e.g., depending on a type of the passive components.

In an exemplary implementation of the semiconductor power entity, the connection metal layer forms a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection provides the advantage that it is a connection which will not remelt or decompose at temperatures much higher than the process temperature it was formed.

In an exemplary implementation of the semiconductor power entity, the connection metal layer forms one of a diffusion soldering connection or a sintering connection.

Diffusion soldering or diffusion bonding is a metal joining technique which can be advantageously applied to electronic packaging. It operates on the principle of interdiffusion of two dissimilar metals, where a liquid phase is completely transformed into solid state by metallic phase reactions and intermetallic compound formation. Similar terms for such technique are transient liquid phase bonding, solid-liquid interdiffusion, isothermal solidification. The technique provides the advantage that the resulting solid phase has a higher melting point than the temperature of the formation process.

Sintering is the process of compacting and forming a solid mass of material by heat or pressure without melting it to the point of liquefaction. Sintering happens as part of a manufacturing process used with metals, ceramics, plastics, and other materials. The atoms in the materials diffuse across the boundaries of the particles, fusing the particles together and creating one solid piece. The advantage of sintering is at least the following: because the sintering temperature does not have to reach the melting point of the material, sintering is often chosen as the shaping process for materials with extremely high melting points.

The connection metal can form a composed metal layer, for example. Such composed metal layer may include a compound from more than two metals, e.g., such as inter-metallic layer, or a connection of metal layers consisting of one single metal, or a connection of a metal and a polymer or polymer mixture.

For such inter-metallic layer, the melting point of the inter metallic layer is higher than the lamination/process temperature where it was formed.

The connection metal layer may consist of more than 80% metal and less than 20% pores or polymers, for example.

The connection metal layer is designed for high current loads.

In one embodiment, the inter-metallic layer may have a minimum lateral size of >1 mm in each dimension, but not smaller than 0.1 mm.

The intermetallic layer may have a large cross-section, short length and good conductor and due to that is suitable for high current loads.

In one embodiment, the connection metal layer may have a thickness of 5 to 50 um, but not thicker than 0.2 mm (in case of a single layer structure).

In an exemplary implementation of the semiconductor power entity, the first laminate layer is embedding a first power semiconductor; and/or the second laminate layer is embedding a second power semiconductor.

Such a semiconductor power entity provides at least the advantage of increased power density and efficiency, short, current-capable low-parasitic interconnection paths, a very good thermal management, and improved electrical isolation. Conductor traces with a high current capability of e.g., several ten amperes up to hundreds of amperes, and power modules with an internal stray inductance, e.g., of a few nH or below can be implemented.

When defining a first power semiconductor and a second power semiconductor this does not exclude that more than one first power semiconductor can be embedded in the first laminate layer and more than one second power semiconductor can be embedded in the second laminate layer.

In an exemplary implementation of the semiconductor power entity, the connection metal layer vertically connects the second metal layer with the third metal layer providing a vertical electrical connection for the first power semiconductor and the second power semiconductor.

This provides at least the advantage that a shortest-path electrically connection can be realized which reduces stray inductance of the power entity and impedance between the two metal layers.

In an exemplary implementation of the semiconductor power entity, the connection metal layer forms a direct electrical connection path between the first power semiconductor and the second power semiconductor without a detour via through-hole vias arranged laterally to the two power semiconductors.

As described above, such a direct electrical connection path provides the advantage of shortest-path large area electrical connection between the two metal layers, reducing impedance and stray inductance.

In an exemplary implementation of the semiconductor power entity, the second metal layer and/or the third metal layer includes at least one of copper, gold, silver, palladium, or nickel, or a combination thereof; where in case of a diffusion soldering connection, the connection metal layer includes any suitable low temperature melting metal, such as tin and indium in combination with any of the metals of the second metal layer or the third metal layer or an alloy thereof; where in case of a sintering connection, the connection metal layer includes a porous layer of silver or copper, or another suitable sintering metal with an optional polymer filling.

This provides at least the advantage that a lot of metals and metal alloys or combinations thereof with different characteristics can be applied

Note that such connection metal layer includes also the following combination: (tin OR indium OR (tin AND indium)) in combination with any of the metals of the second metal layer or the third metal layer or an alloy thereof.

In an exemplary implementation of the semiconductor power entity, the first power semiconductor and the second power semiconductor are configured to form a half bridge configuration. It can be understood that a lot of other configurations of the two power semiconductors can be implemented as well.

This provides at least the advantage that the semiconductor power entity can be efficiently used in automotive power conversion systems and in other applications of the semiconductor power entity. The half bridge configuration is a reoccurring key topology element in power electronics conversion circuits.

In an exemplary implementation of the semiconductor power entity, the first power semiconductor is a vertical device including at least one first terminal opposing the first laminate upper main face and a second terminal opposing the first laminate lower main face; and the second power semiconductor is a vertical device including at least one first terminal opposing the second laminate upper main face and a second terminal opposing the second laminate lower main face.

This provides at least the advantage that the semiconductor power entity can provide high current density, high power dissipation, and high reverse breakdown voltage.

In an alternative exemplary implementation of the semiconductor power entity, the first power semiconductor can be a lateral device and the second power semiconductor can be a lateral device.

In an exemplary implementation of the semiconductor power entity, as described below with respect to FIG. 2A, the semiconductor power entity includes: at least one first via and at least one second via extending through the first laminate layer, the at least one first via forming an electrical connection between the at least one first terminal of the first power semiconductor and the first metal layer and the at least one second via forming an electrical connection between the second terminal of the first power semiconductor and the second metal layer; and at least one third via and at least one fourth via extending through the second laminate layer, the at least one third via forming an electrical connection between the at least one first terminal of the second power semiconductor and the third metal layer and the at least one fourth via forming an electrical connection between the second terminal of the second power semiconductor and the fourth metal layer.

Such an embodiment provides at least the advantage that the shortest path between the two facing inner terminals of the power semiconductors can be used for electrical connection. This results in low parasitic impedance, high current capability of this buried connection due to large area. It can be even made larger than the die itself. Without the provided technique, such connections are only possible by arrangement of through-holes at the periphery outside the projected die area.

By such an embodiment, both power semiconductors can be fully embedded in the respective laminate layers which results in excellent electrical performance.

In an alternative embodiment, as shown below with respect to FIGS. 2C to 2E, these vias can be replaced by large area connections such that either the die front or the die back side can be in direct connection to the metal layers without any distance. Note that the large area connections can be made on one face of the chip per layer. With development and process modification large area connections can be on both sides, but in such a case there most likely would be one large area connection/via instead of multiple small vias.

These large area connections have the advantage that configurations are possible that allow further optimization of a) parasitic impedance by shortening the electrical path, or b) thermal path by enabling direct heat extraction without microvias at the outer surface of the entity.

In an exemplary implementation of the semiconductor power entity, as described below with respect to FIGS. 4A to 4D and FIG. 5, the first power semiconductor has a first semiconductor upper main face and a first semiconductor lower main face opposing the first semiconductor upper main face; where the first semiconductor upper main face is coplanar arranged with the first laminate upper main face to form an electrical connection between the at least one first terminal of the first power semiconductor and the first metal layer at the first laminate upper main face; and where the second terminal of the first power semiconductor forms an electrical connection with the second metal layer at the first laminate lower main face by one or more microvias extending through the first laminate layer. Alternatively, the first semiconductor lower main face is coplanar arranged with the first laminate lower main face to form an electrical connection between the second terminal of the first power semiconductor and the second metal layer at the first laminate lower main face; and where the at least one first terminal of the first power semiconductor forms an electrical connection with the first metal layer at the first laminate upper main face by one or more microvias extending through the first laminate layer.

Such an embodiment provides at least the advantage of large area chip connection on one side of the chip with the respective metal layer which provides improved thermal dissipation and improved electrical performance.

In an exemplary implementation of the semiconductor power entity, the second power semiconductor has a second semiconductor upper main face and a second semiconductor lower main face opposing the second semiconductor upper main face; where the second semiconductor upper main face is coplanar arranged with the second laminate upper main face to form an electrical connection between the at least one first terminal of the second power semiconductor and the third metal layer at the second laminate upper main face; and where the second terminal of the second power semiconductor forms an electrical connection with the fourth metal layer at the second laminate lower main face by one or more microvias extending through the second laminate layer. Alternatively, the second semiconductor lower main face is coplanar arranged with the second laminate lower main face to form an electrical connection between the second terminal of the second power semiconductor and the fourth metal layer at the second laminate lower main face; and where the at least one first terminal of the second power semiconductor forms an electrical connection with the third metal layer at the second laminate upper main face by one or more microvias extending through the second laminate layer.

Such an embodiment provides at least the same advantage of large area chip connection on one side of the chip with the respective metal layer as described above. This large area chip connection results in improved thermal dissipation and improved electrical performance.

According to the second aspect, the embodiments relate to a method for producing a semiconductor power entity, as described below with respect to FIGS. 4A to 4D and FIG. 5, the method including: providing a first laminate layer embedding a first power semiconductor, the first laminate layer having a first laminate upper main face and a first laminate lower main face opposing the first laminate upper main face; where a first metal layer is arranged at the first laminate upper main face of the first laminate layer and a second metal layer is arranged at the first laminate lower main face of the first laminate layer; providing a second laminate layer embedding a second power semiconductor, the second laminate layer having a second laminate upper main face and a second laminate lower main face opposing the second laminate upper main face; where a third metal layer is arranged at the second laminate upper main face of the second laminate layer and a fourth metal layer is arranged at the second laminate lower main face of the second laminate layer; applying a bonding metal at the second metal layer of the first laminate layer and/or the third metal layer of the second laminate layer, the bonding metal being placed between the first power semiconductor and the second power semiconductor and/or between respective electrical contact pairs in the first laminate layer and the second laminate layer, arranging an isolation layer between the second metal layer of the first laminate layer and the third metal layer of the second laminate layer; and laying-up and laminating the first laminate layer, the second laminate layer and the isolation layer to a semiconductor power entity, where the laminating transforms the bonding metal to a connection metal layer forming an electrical connection with the second metal layer and the third metal layer.

Such method or process provides at least the advantage to form the above-described vertical connections. The method or process provides the following advantageous characteristics: use of a standard PCB lamination process with respect to bond temperature, pressure, format; use of hybrid bonding to bond metal to metal and dielectric to dielectric in one step; several premanufactured layers can be connected to each other in one lamination step or in several sequential lamination steps; and the bonding materials can be attached or applied to the surface of the laminate layers or placed between the laminate layers prior to bonding.

In an exemplary implementation of the method, the connection metal layer is formed simultaneously with the lamination of the first laminate layer, the second laminate layer and the isolation layer.

This provides at least the advantage that the fabrication method can be simplified due to performing two production steps simultaneously.

In an exemplary implementation of the method, as described below with respect to FIG. 4A, the method includes: applying the bonding metal at the second metal layer of the first laminate layer; before the laying-up and laminating; and applying the isolation layer at the third metal layer of the second laminate layer before the laying-up and laminating, where the isolation layer is structured to form an opening for embedding the bonding metal.

This provides at least the advantage of flexibility in the sequence of the different production steps. It does not matter, for example, to which laminate layer the bonding metal or the isolation layer is applied to. They only need to be complementary.

In an exemplary implementation of the method, applying the bonding metal includes plating of metals, printing or dispending of pastes, placing of preforms; and where applying the isolation layer includes printing, coating, laminating or dispensing of dielectric material.

This provides at least the advantage of providing alternatives for application of the bonding metal and application of the isolation layer.

In an exemplary implementation of the method, as described below with respect to FIG. 4D, the method includes: applying the isolation layer at the third metal layer of the second laminate layer before the laying-up and laminating, where the isolation layer is structured to form an opening for embedding the bonding metal; and placing the bonding metal into the opening of the isolation layer on the third metal layer.

This provides at least the advantage of flexibility in the sequence of the different production steps.

In an exemplary implementation of the method, as described below with respect to FIG. 4B, the method includes: placing the isolation layer between the second metal layer of the first laminate layer and the third metal layer of the second laminate layer during the laying-up and laminating, where the isolation layer is non-structured.

This provides at least the advantage of flexibility in the sequence of the different production steps.

In an exemplary implementation of the method, as described below with respect to FIG. 4C, the method includes: placing the isolation layer between the second metal layer of the first laminate layer and the third metal layer of the second laminate layer during the laying-up and laminating, where the isolation layer is structured to form an opening for embedding the bonding metal.

This provides at least the advantage of providing alternatives for placement of the isolation layer.

Following process steps of the above method are optional: drilling holes in the semiconductor power entity extending from the first metal layer to the fourth metal layer, where the holes are drilled laterally to the first and second power semiconductors; metal plating the holes to form metal plated through holes electrically connecting the first and optionally second, third metal layers with the fourth metal layer; and structuring the first metal layer and the fourth metal layer.

According to the third aspect, the embodiments relate to a computer program product including computer executable code or computer executable instructions that, when executed, causes at least one computer to execute the method according to the second aspect described above.

The computer program product may run on a controller or a processor for implementing the above method to produce the semiconductor power entity according to the first aspect described above.

According to a fourth aspect, the embodiments relate to a computer-readable medium, storing instructions that, when executed by a computer, cause the computer to execute the method according to the second aspect described above. Such a computer-readable medium may be a non-transient readable storage medium, otherwise referred to as a non-transitory computer-readable medium. The instructions stored on the non-transitory computer-readable medium may be executed by a controller or a processor.

According to a fifth aspect, the embodiments relate to a hybrid bond sheet for bonding a first joining member to a second joining member, the hybrid bond sheet including: a core layer having an upper main face and a lower main face opposing the upper main face, the core layer including: a core insulating layer formed between the upper main face and the lower main face; and one or more metallic through-connections penetrating the core insulating layer from the upper main face to the lower main face; a first bonding layer for bonding the first joining member, the first bonding layer being formed at the upper main face of the core layer, the first bonding layer including: a first insulating bond layer formed on the core insulating layer and a first metal bond layer formed on the one or more metallic through-connections; and a second bonding layer for bonding the second joining member, the second bonding layer being formed at the lower main face of the core layer, the second bonding layer including a second insulating bond layer formed on the core insulating layer and a second metal bond layer formed on the one or more metallic through-connections; where the one or more metallic through-connections and the first and second metal bond layers are configured to form an electrically and thermally conductive connection with the first joining member and the second joining member.

Such a hybrid bond sheet can be efficiently applied for bonding two joining members, e.g., two PCB layers or laminate layers. The hybrid bond sheet has improved thermal characteristics and can be advantageously applied in the manufacturing of semiconductor power entities.

In the embodiments, hybrid bond sheet means that bonding of the 2 joining members includes more than one (here: 2) bonding mechanisms, an electrically conductive metallurgical bond, and a dielectric, electrically isolating bond. The 2 bond mechanisms act in laterally separated partial areas of the bond sheet, which is brought in between the 2 joining partners.

The hybrid bond sheet presented in the embodiments can be used as a thermal management sheet.

In an exemplary implementation of the hybrid bond sheet, the first joining member, and/or the second joining member include at least one or a combination of a laminate layer, a mold layer, a metal-structured laminate or mold layer, an embedded component layer, a redistribution metallization layer, and an interposer layer.

This provides at least the advantage that the hybrid bond sheet can be flexible applied to a variety of joining members.

In an exemplary implementation of the hybrid bond sheet, the core insulating layer includes at least one or a combination of the following: a printed circuit board laminate, a mold sheet, an Ajinomoto build-up film (ABF), a molded interconnect substrate (MIS), a polymer composite material, and a polymer sheet material.

This provides at least the advantage that the hybrid bond sheet and the core insulating layer of the hybrid bond sheet can be flexible designed by using a variety of materials.

In an exemplary implementation of the hybrid bond sheet, the one or more metallic through-connections include at least one or a combination of the following components: metal vias, metal bars, metal spacers, metal studs, metal bumps, and metal balls.

This provides at least the advantage that the hybrid bond sheet and the metallic through-connections of the hybrid bond sheet can be flexible designed by using a variety of different metals and metal shapes.

In an exemplary implementation of the hybrid bond sheet, the one or more metallic through-connections includes a first part being formed at the upper main face of the core layer and a second part being formed at the lower main face of the core layer.

This provides at least the advantage that the metallic through-connections can be designed in a variety of different structures.

In specific applications, the first part and the second part can be shaped differently.

In an exemplary implementation of the hybrid bond sheet, the one or more metallic through-connections include fully metallized non-sectioned or sectioned through-connections.

Fully metallized in the embodiments means made of full metal, i.e., not sectioned into first/second part, cross-section does not change in z direction, or 1^{st}/2^{nd} part shaped equally.

Fully metallized in the context of the embodiments shall mean that the metallic through-connection includes a fully metallized body without a polymer core.

In contrast, partially metallized in the embodiments shall mean that only the sidewall of a through-connection is covered with metal.

Non-sectioned in the context of the embodiments shall mean that the metallic through-connections are not sectioned into first/second part, the cross-section does not change in z-direction, or 1^{st}/2^{nd} part is shaped equally.

In contrast, sectioned in the embodiments shall mean that the metallic through-connections can be vertically divided into 2 or more sections with different shape and/or diameter.

In another exemplary implementation of the hybrid bond sheet, the one or more metallic through-connections are sectioned into a 1^{st}/2^{nd} part, each of which may have different shapes.

A reason and advantage for the sectioning is clearance of conductor traces when there are two metal areas that should be isolated, but one of them should have higher current capability.

Another reason and advantage for the sectioning is adhesion and stability of the mold sheet. The inner surface is increased by the step, the metal part is better locked into the core layer, providing higher stability during handling of the sheet in production.

In an exemplary implementation of the hybrid bond sheet, the one or more metallic through-connections includes at least two fully metallized non-sectioned through-connections of any shape.

This provides at least the advantage that the hybrid bond sheet can provide flexible current capabilities of the at least two fully metallized non-sectioned through-connections.

In an exemplary implementation of the hybrid bond sheet, the one or more metallic through-connections include at least two fully metallized sectioned through-connections of any shape.

This provides at least the advantage of adding mechanical stability to the sheet. These through-connections can also include more than two sections with the capability to create a locking/anchoring structure to safely prevent the through-connection “bars” to detach or fall out of the core layer.

In an exemplary implementation of the hybrid bond sheet, the one or more metallic through-connections include at least one sectioned metallic through-connection including a first part and a second part of different diameters and/or shapes for locking and/or anchoring the sectioned metallic through-connection into the core layer.

This provides at least the advantage of efficiently locking or anchoring the sectioned metallic through-connection into the core layer.

In an exemplary implementation of the hybrid bond sheet, the at least one sectioned metallic through-connection includes two sections, where contours of the two sections have notches at mutually exclusive alternating positions at regular intervals of a contour circumference. This provides at least the advantage of design flexibility.

In an exemplary implementation of the hybrid bond sheet, the at least one sectioned metallic through-connection includes two sections, where contours of the two sections have complementary undulating outlines. This provides at least the advantage of design flexibility.

In an exemplary implementation of the hybrid bond sheet, the at least one sectioned metallic through-connection includes two sections, where one section has an equal triangular rounded corner outline, and the other section has a 60° rotated outline. This provides at least the advantage of design flexibility.

In an exemplary implementation of the hybrid bond sheet, the at least one sectioned metallic through-connection includes three sections, where a middle section of the three sections is smaller or larger than an upper and lower section of the three sections. This provides at least the advantage of design flexibility.

In an exemplary implementation of the hybrid bond sheet, the joining members are functional layers, each one including an outer metallization; where one or both of the first metal bond layer and the second metal bond layer form a non-remelting electrical and mechanical connection with the outer metallization of the joining members.

This provides at least the advantage that the hybrid bond sheet can provide a mechanically stable and thermally and electrically high conductive connection between the two functional layers.

In an exemplary implementation of the hybrid bond sheet, the joining members are functional layers, each one including an outer metallization; where one or both of the first metal bond layer and the second metal bond layer form one of a diffusion soldering connection, a sintering connection or a nano-hair Velcro bonding connection with the outer metallization of the joining members.

The advantage of the diffusion soldering is at least that the resulting solid phase has a higher melting point than the temperature of the formation process. The advantage of the sintering is that because the sintering temperature does not have to reach the melting point of the material, sintering is advantageous for materials with extremely high melting points.

In an exemplary implementation of the hybrid bond sheet, the first insulating bond layer and the second insulating bond layer form an electrically isolating bond connection between the joining members.

The electrically isolating bond connection provides at least the advantage of dielectric breakdown strength, mechanical stability, protection and insulation against moisture and contamination of the interface between the joining partners.

In an exemplary implementation of the hybrid bond sheet, the one or more metallic through-connections are arranged in a predetermined pattern that is aligned with a structure of the first joining member and/or the second joining member.

This provides at least the advantage of defining the product-specific contact scheme. The bond sheets are uniquely designed to match exactly their respective joining partner surfaces.

In an exemplary implementation of the hybrid bond sheet, the one or more metallic through-connections are arranged in a predetermined pattern having a uniform structure to support a universal contact scheme for different products and/or applications.

This provides at least the advantage of defining the universal contact scheme with a repetitive raster-like pattern that matches many products.

In an exemplary implementation of the hybrid bond sheet, the first insulating bond layer and/or the second insulating bond layer are made of thermosetting material.

This provides at least the advantage that after curing, the thermosetting material will not remelt, even at higher temperatures (below decomposition temperature) than the curing temperature.

According to a sixth aspect, the embodiments relate to a semiconductor power entity, including: a first joining member having a first upper main face and a first lower main face opposing the first upper main face, the first joining member including a first metal layer arranged at the first upper main face and a second metal layer arranged at the first lower main face; a second joining member having a second upper main face and a second lower main face opposing the second upper main face, the second joining member including a third metal layer arranged at the second upper main face and a fourth metal layer arranged at the second lower main face; and a hybrid bond sheet according to the fifth aspect formed between the first joining member and the second joining member; where the one or more metallic through-connections and the first and second metal bond layers of the hybrid bond sheet form an electrically and thermally conductive connection with the second metal layer and the third metal layer of the first joining member and the second joining member; and where the first insulating bond layer and the second insulating bond layer of the hybrid bond sheet form an electrically isolating bond connection between the joining members.

Such a semiconductor power entity provides at least the advantage that the isolating bond connection provides dielectric breakdown strength, mechanical stability, protection, and insulation against moisture and contamination of the interface between the joining partners.

In an exemplary implementation of the semiconductor power entity, the first joining member is embedding a first power semiconductor, and/or the second joining member is embedding a second power semiconductor.

This provides at least the advantage that the semiconductor power entity can be manufactured using a hybrid bond sheet that bonds joining members such as PCB layers which are embedding one or more power semiconductors.

In an exemplary implementation of the semiconductor power entity, the one or more metallic through-connections and the first and second metal bond layers of the hybrid bond sheet form a direct electrical connection path between the first power semiconductor and the second power semiconductor without a detour via through-hole vias arranged laterally to the two power semiconductors.

Such a direct electrical connection path provides at least the advantage of shortest-path large area electrical connection between the two power semiconductors, reducing impedance and stray inductance.

According to a seventh aspect, the embodiments relate to a method for producing a semiconductor power entity, the method including: providing a first joining member embedding a first power semiconductor, the first joining member having a first upper main face and a first lower main face opposing the first upper main face; where a first metal layer is arranged at the first upper main face of the first joining member and a second metal layer is arranged at the first lower main face of the first joining member; providing a second joining member embedding a second power semiconductor, the second joining member having a second upper main face and a second lower main face opposing the second upper main face; where a third metal layer is arranged at the second upper main face of the second joining member and a fourth metal layer is arranged at the second lower main face of the second joining member; forming a hybrid bond sheet according to the fifth aspect between the first joining member and the second joining member and laying-up the first joining member, the second joining member and the hybrid bond sheet; and laminating the layed-up first joining member, second joining member and hybrid bond sheet to a semiconductor power entity, where the laminating transforms the one or more metallic through-connections and the first and second metal bond layers of the hybrid bond sheet to form an electrically and thermally conductive connection with the second metal layer and the third metal layer of the first joining member and the second joining member; and where the laminating cures the insulating bond layers of the hybrid bond sheet to form an electrically isolating bond connection between the joining members.

Such method or process provides at least the advantage to form the above-described vertical connections between the two joining members. The method or process provides the following advantageous characteristics: use of a standard PCB lamination process with respect to bond temperature, pressure, format; use of hybrid bond sheet to bond metal to metal and dielectric to dielectric in one step; and several premanufactured layers can be connected to each other in one lamination step or in several sequential lamination steps.

At least a further advantage is that the laminating may simultaneously cure the isolating bond layers bonding together all surfaces in contact and embedding/encapsulating the joined metal layers.

At least a further advantage of providing a hybrid bond sheet for bonding the joining partners is a simplification/complexity reduction of the assembly process. The bond sheet could be supplied/provided separately and the bond materials do not need to be directly applied to the joining partners in-line/in-situ. This decouples the manufacturing process and provides higher flexibility to the production flow or a smoother production flow.

### BRIEF DESCRIPTION OF THE DRAWINGS

Further embodiments will be described with respect to the following figures, in which:

FIG. 1A shows a schematic diagram illustrating production of a semiconductor power product without using hybrid bonding according to the embodiments;

FIG. 1B shows a schematic diagram illustrating production of a semiconductor power product using hybrid bonding according to the embodiments;

FIG. 2A shows a schematic cross section of a semiconductor power entity according to a first embodiment;

FIG. 2B shows a schematic cross section of a semiconductor power entity according to a second embodiment;

FIG. 2C shows a schematic cross section of a semiconductor power entity according to a third embodiment;

FIG. 2D shows a schematic cross section of a semiconductor power entity according to a fourth embodiment;

FIG. 2E shows a schematic cross section of a semiconductor power entity according to a fifth embodiment;

FIG. 3A shows one-layer, single sided metal stack as an option for producing the metal stack for panel level hybrid bonding according to the embodiments;

FIG. 3B shows one-layer, double sided metal stack as another option for producing the metal stack for panel level hybrid bonding according to the embodiments;

FIG. 3C shows multi-layer, single or double sided metal stack as another option, for producing the metal stack for panel level hybrid bonding according to the embodiments;

FIG. 3D shows pre-form metal stack as another option for producing the metal stack for panel level hybrid bonding according to the embodiments;

FIG. 4A shows a process flow diagram of a method for producing a semiconductor power entity according to a first embodiment referring to resin printing;

FIG. 4B shows a process flow diagram of a method for producing a semiconductor power entity according to a second embodiment referring to non-structured resin sheet;

FIG. 4C shows a process flow diagram of a method for producing a semiconductor power entity according to a third embodiment referring to structured prepreg or resin sheet;

FIG. 4D shows a process flow diagram of a method for producing a semiconductor power entity according to a fourth embodiment referring to preform placement;

FIG. 5 shows a schematic diagram illustrating a method for producing a semiconductor power entity according to the embodiments;

FIG. 6 shows a schematic cross section of a semiconductor power entity with a hybrid bond sheet 200 according to the embodiments;

FIG. 7 shows a schematic cross section of a structure or process for a pre-manufactured hybrid bond sheet with a customized contact pattern;

FIG. 8 shows a schematic cross section of a structure or process for a pre-manufactured hybrid bond sheet with a uniform contact pattern;

FIG. 9 shows a schematic cross section of a structure or process for a pre-manufactured hybrid bond sheet supporting a power or logic stacked package configuration; and

FIG. 10 shows examples of the metallic through connections shown in FIGS. 6 to 9.

### DETAILED DESCRIPTION OF EMBODIMENTS

In the following, reference is made to the accompanying drawings, which form a part thereof, and in which is shown by way of illustration specific aspects in which the embodiments may be practiced. It is understood that other aspects may be utilized and structural or logical changes may be made without departing from the scope of the embodiments. The following detailed description, therefore, is not to be taken in a limiting sense, and the scope of the embodiments is not limited thereby.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

In the embodiments, diffusion soldering is described. The principle of diffusion soldering is applied to microelectronics since the 1960ies. It is also known as SLID, TLPB (transient liquid phase bonding), or isothermal solidification. It was since then applied to 3D-integration/chip-stacking and MEMS wafer level encapsulation. Diffusion soldering is an irreversible process, the connection does not remelt at the same temperature it is formed, but at a much higher temperature because all low-temperature melting solder is transformed into intermetallic compounds which have a higher melting temperature.

In the embodiments, sintering is described. Sintering is another low temperature metal joining technology that allows to make non-remeltable stable and reliable connections at a relatively low bond temperature. It is based on the high self-diffusion and surface diffusion property of some metals (Silver and Copper are commonly known and applied today), such as if the initially surface is very large. In some embodiments, a paste is printed and dried on a noble metal surface. The paste contains silver particles of different sizes and with a specific coating that prevents premature agglomeration and unwanted sintering. Under temperature and pressure, the dried paste densifies into a porous metal layer that forms a metallurgical bond with the compatible metal surfaces in contact. Another way to offer large sinterable metal surfaces is in form of metal filaments or wires that are grown on the contact surface, with diameters in the lower μm down to upper nm range and lengths of several tens of μm.

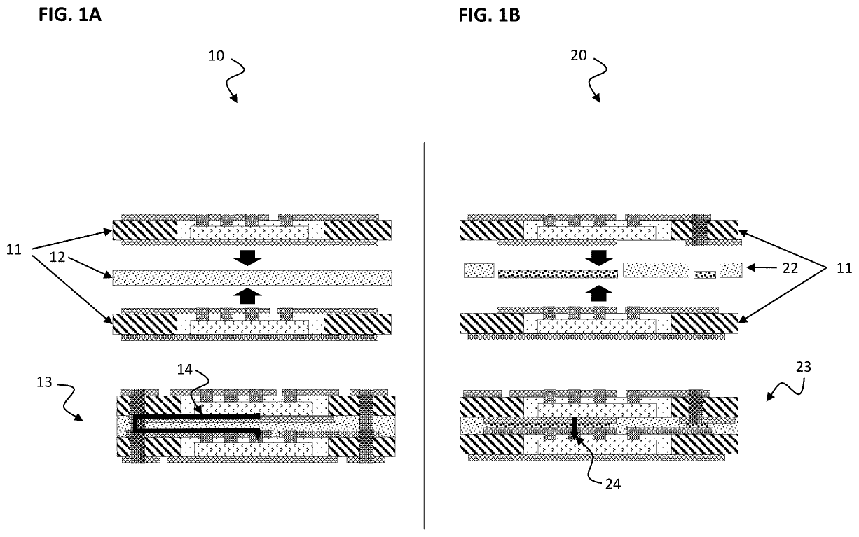

FIG. 1A shows a schematic diagram illustrating production 10 of a semiconductor power product 13 without using hybrid bonding according to the embodiments; while FIG. 1B shows a schematic diagram illustrating production 20 of a semiconductor power product 23 using hybrid bonding according to the embodiments.

In FIG. 1A, two laminate embedded power die panels 11 are provided and a prepreg sheet 12 in between. After lamination a semiconductor power product 13 with a stacked die half-bridge is produced. No direct vertical connections between the stacked dies are possible.

The semiconductor power product 13 is characterized by an indirect electrical path 14 with high parasitics (R, L) and an interrupted thermal path.

In FIG. 1B, the two laminate embedded power die panels 11 are provided and hybrid bond materials 22 in between. After lamination a semiconductor power product 23 with a stacked die half-bridge is produced. The hybrid bonding method enables direct vertical connections 24 for large currents.

In contrast to the semiconductor power product 13 of FIG. 1A, semiconductor power product 23 shown in FIG. 1B is characterized by direct electrical path 24, low parasitics (R, L) and continuous thermal path.

The embodiments present a method how two or more laminate layers, (with or without embedded dies), e.g., two or more of the laminate embedded power die panels 11 shown in FIG. 1B, can be vertically connected with respect to each other using panel level PCB mass production equipment. This method combines chip embedding and PCB lamination with low temperature metal joining technology. The low temperature metal joining technology can be either based on diffusion soldering (e. g., SLID solid liquid interdiffusion, TLPB transient liquid phase bonding) or sintering (e.g., Ag sintering, Cu sintering, nano filament assisted sintering).

One idea of the embodiments is that during one single process step, the metal areas can be electrically and thermally connected using SLID bonding, diffusion bonding, sintering, or nano wires, and the other areas can be bonded, laminated, or glued together with nonconductive polymer material. The bonding process can be performed at a relatively low temperature. The metals and polymer bonding materials can be selected in such a way that the bonding can be realized in approximately the same or lower temperature than the curing of the polymer bonding material. The method allows to irreversibly connect two layers with embedded components vertically together with a non-remeltable connection that allows excellent electrical and thermal performance and high reliability.

The hybrid bonding method according to the embodiments includes the following steps: providing the laminate with redistribution layer (RDL); applying bond materials to the bond surfaces of the laminates or panels to be connected, e.g., metallization for SLID, TLPS, polymer/glue; the lay-up step; the lamination/bonding step; and the singulation step. It may be understood that additional PCB processes can be done between these steps.

Several possible options for the application of the materials to the bond surface, the structure of the bond materials, and the interaction of the bond materials with the bond surface are described below.

These embodiments provide an essential building block for power packaging on panel level, such as for laminate based large scale packaging. It enables more degrees of freedom in design of current capable in-package electrical and thermal connections in the vertical dimension. The vertical connections can have different areas and shapes by design. They can be used to effectively shorten critical conductor lengths or strengthen the thermal path.

Using hybrid bonding as shown in FIG. 1B provides the following benefits: a) simultaneous metal/metal and polymer/polymer bonding leads to fewer process steps, no underfill process necessary; b) high reliable and non-meltable low parasitics electrical interconnection between laminate layers; c) 3D integrated of power devices; vertical stacked packaging with up to 2× increase of power density; d) panel level packaging of vertically stacked devices; processing and tooling cost down; e) make direct vertical connections inside the package and reduce package parasitics (noting that this kind of embedded connections between layers that are laminated together are not possible with conventional PCB processes); and f) make thermal connections to a heatsink using a panel level lamination process.

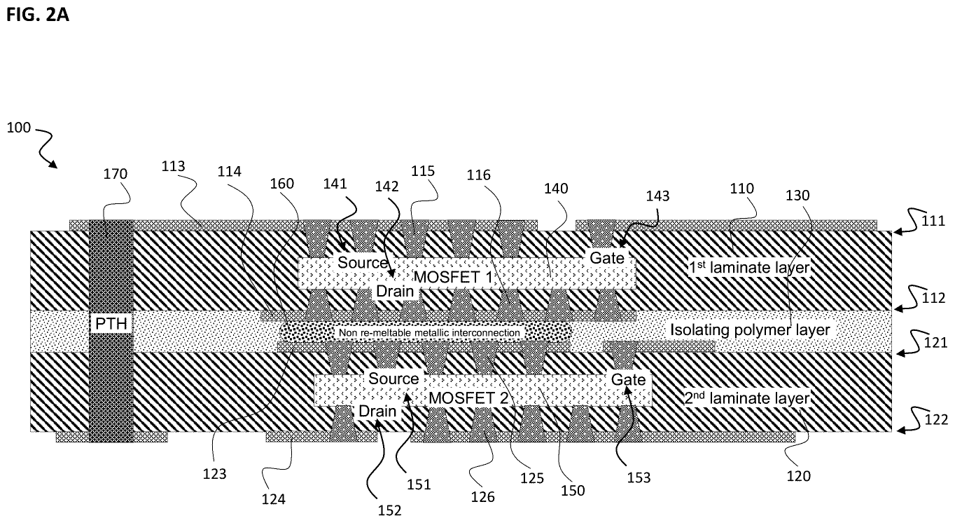

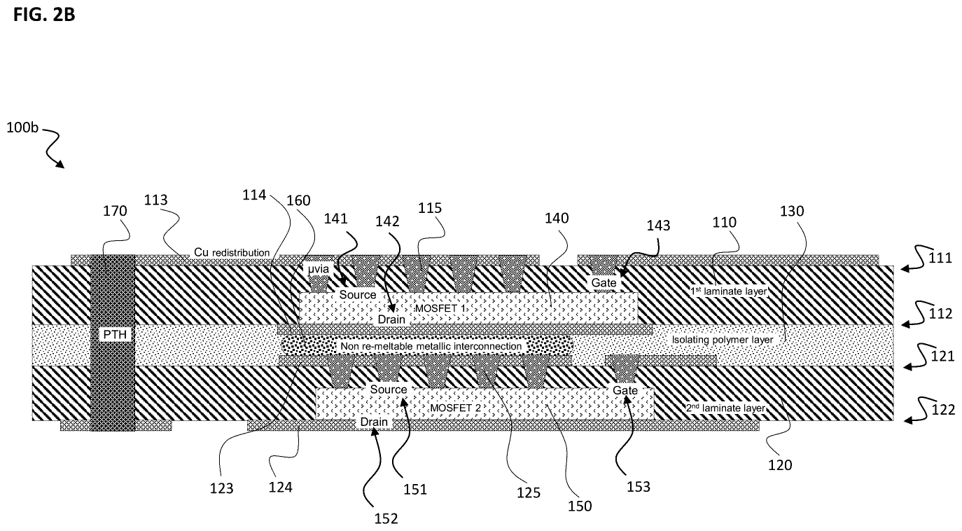

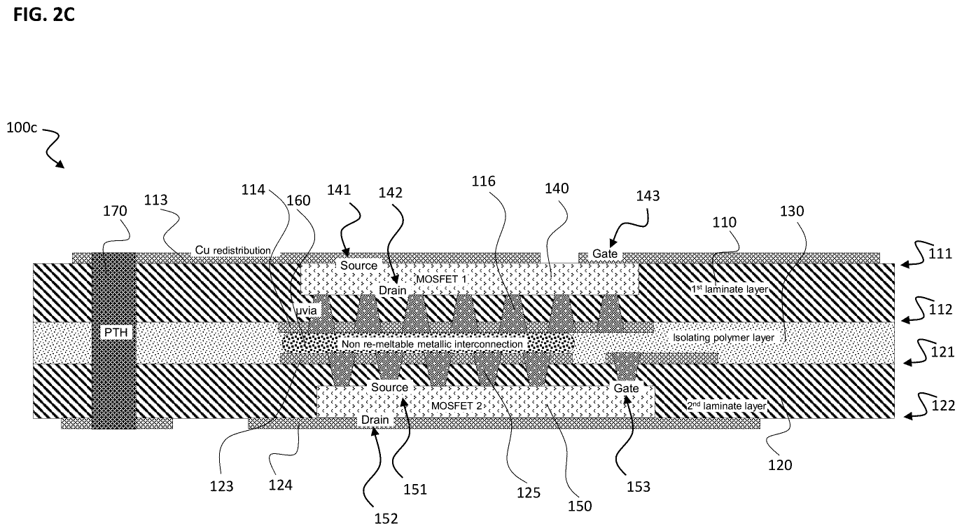

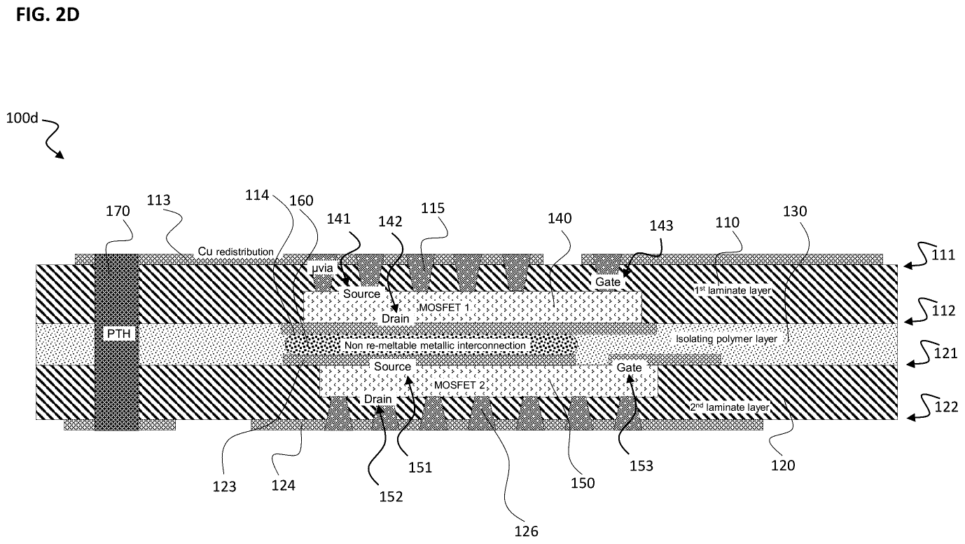

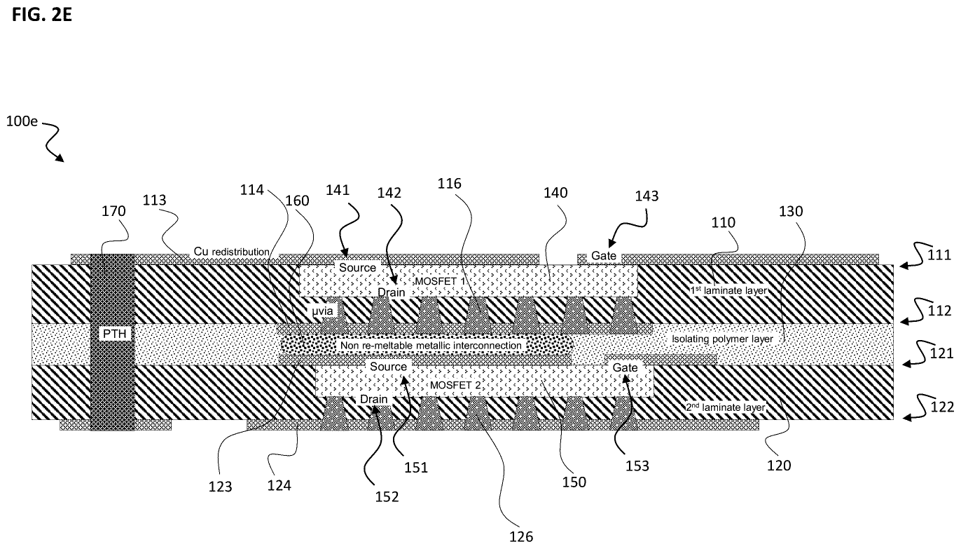

FIG. 2A shows a schematic cross section of a semiconductor power entity 100 according to a first embodiment.

The semiconductor power entity 100, also referred to as a semiconductor power product, includes a first laminate layer 110 having a first laminate upper main face 111 and a first laminate lower main face 112 opposing the first laminate upper main face 111; and a second laminate layer 120 having a second laminate upper main face 121 and a second laminate lower main face 122 opposing the second laminate upper main face 121.

The semiconductor power entity 100 includes an isolation layer 130 arranged between the first laminate layer 110 and the second laminate layer 120.

The semiconductor power entity 100 includes a first metal layer 113 arranged at the first laminate upper main face 111 of the first laminate layer 110 and a second metal layer 114 arranged at the first laminate lower main face 112 of the first laminate layer 110.

The semiconductor power entity 100 includes a third metal layer 123 arranged at the second laminate upper main face 121 of the second laminate layer 120 and a fourth metal layer 124 arranged at the second laminate lower main face 122 of the second laminate layer 120.

The semiconductor power entity 100 includes a connection metal layer 160 embedded in the isolation layer 130 between the first laminate layer 110 and the second laminate layer 120. The connection metal layer 160 is forming an electrical connection with the second metal layer 114 and the third metal layer 123.

The first, second, third and fourth metal layers 113, 114, 123, 124 can be redistribution or routing metal layers for redistributing or routing current paths.

As mentioned above, the semiconductor power entity can also be referred to as semiconductor power product. Such product can also be a module or a larger size product (PCB), for example, where the power components are embedded inside the PCB and the rest of the components on top. As described above, also part of the passives can be embedded inside the PCB.

The connection metal layer 160 can form a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection is a connection which does not remelt in same temperatures at which the connection was formed.

The connection metal layer 160 can form one of a diffusion soldering connection or a sintering connection as described above in the section “detailed description of embodiments”.

The connection metal 160 can form a composed metal layer, for example. Such composed metal layer may include a compound from more than two metals, e.g., such as inter-metallic layer, or a connection of metal layers having one single metal, or a connection of a metal and a polymer or polymer mixture.

For such inter-metallic layer, the melting point of the inter metallic layer is higher than the lamination/process temperature where it was formed.

The connection metal layer may include more than 80% metal and less than 20% pores or polymers, for example.

The connection metal layer is designed for high current loads.

In one embodiment, the inter-metallic layer may have a minimum lateral size of greater than 1 mm in each dimension, but not smaller than about 0.1 mm.

The intermetallic layer may have a large cross-section, short length, and good conductor and due to that is suitable for high current loads.

In one embodiment, the inter-metallic layer may have a thickness of about 5 to 50 μm, but not thicker than about 0.2 mm (in case of a single layer structure).

As mentioned above, the laminate layers may embed or not embed power dies.

The first laminate layer 110 may embed a first power semiconductor 140 as shown in FIG. 2A and/or the second laminate layer 120 may embed a second power semiconductor 150 as shown in FIG. 2A. In one example, only one of the laminate layers 110, 120 may be embedding a semiconductor component.

When defining a first power semiconductor and a second power semiconductor this does not exclude that more than one first power semiconductor can be embedded in the first laminate layer 110 and more than one second power semiconductor can be embedded in the second laminate layer 120.

The connection metal layer 160 may vertically connect the second metal layer 114 with the third metal layer 123 providing a vertical electrical connection for the first power semiconductor 140 and the second power semiconductor 150.

The connection metal layer 160 may form a direct electrical connection path between the first power semiconductor 140 and the second power semiconductor 150 without a detour via through-hole vias arranged laterally to the two power semiconductors 140, 150, e.g., as exemplarily illustrated by the direct connection path 24 in FIG. 1B.

The second metal layer 114 and/or the third metal layer 123 may include at least one of copper, gold, silver, palladium, or nickel, or a combination thereof. In case of a diffusion soldering connection, the connection metal layer 160 may include any of a suitable low temperature melting metal like for example the metals tin and indium in combination with any of the metals of the second metal layer 114 or the third metal layer 123 or an alloy thereof. In case of a sintering connection, the connection metal layer 160 may include a porous layer of silver or copper or other suitable sintering metal with optional polymer filling.

Note that such connection metal layer can include also the following combination: (tin OR indium OR (tin AND indium)) in combination with any of the metals of the second metal layer (114) or the third metal layer (123) or an alloy thereof.

The first power semiconductor 140 and the second power semiconductor 150 may be configured to form a half bridge configuration.

The first power semiconductor 140 can be a vertical device including at least one first terminal 141, 143 (e.g., source 141 and gate 143 as shown in FIG. 2A) opposing the first laminate upper main face 111 and a second terminal 142 (e.g., drain 142 as shown in FIG. 2A) opposing the first laminate lower main face 112.

The second power semiconductor 150 can be a vertical device including at least one first terminal 151, 153 (e.g., source 151 and gate 153 as shown in FIG. 2A) opposing the second laminate upper main face 121 and a second terminal 152 (e.g., drain 152 as shown in FIG. 2A) opposing the second laminate lower main face 122.

The semiconductor power entity 100 may include at least one first via 115 and at least one second via 116 extending through the first laminate layer 110. The at least one first via 115 may form an electrical connection between the at least one first terminal 141, 143 of the first power semiconductor 140 and the first metal layer 113. The at least one second via 116 may form an electrical connection between the second terminal 142 of the first power semiconductor 140 and the second metal layer 114.

The semiconductor power entity 100 may include at least one third via 125 and at least one fourth via 126 extending through the second laminate layer 120. The at least one third via 115 may form an electrical connection between the at least one first terminal 151, 153 of the second power semiconductor 150 and the third metal layer 123. The at least one fourth via 126 may form an electrical connection between the second terminal 152 of the second power semiconductor 150 and the fourth metal layer 124.

In an alternative embodiment as described below with respect to FIGS. 2B to 2E, the vias 115, 116 can be replaced by large area connections such that the die front or back side can be in direct connection to the metal layers 113, 123 without any distance. Note that the large area connections can be made on one face of the chip per layer as exemplified in FIGS. 2B to 2e. With development and process modification large area connection can be on both sides (but in such a case there most likely would be one large area connection/via instead of multiple small vias).

FIG. 2B shows a schematic cross section of a semiconductor power entity 100b according to a second embodiment. In this second embodiment, a direct electrical and thermal path of lower power semiconductor to outer surface of power entity can be implemented. This corresponds to the scenario where a high side switch of a half-bridge configuration has direct electrical and thermal path to outer surface of power entity.

This second embodiment is similar to the first embodiment, but the first power semiconductor 140 is directly connected to the second metal layer 114 without applying vias. Similarly, the second power semiconductor 150 is directly connected to the fourth metal layer 124 without applying vias in between.

In this second embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor lower main face is coplanar arranged with the first laminate lower main face 112 to form an electrical connection between the second terminal 142 of the first power semiconductor 140 and the second metal layer 114 at the first laminate lower main face 112. The at least one first terminal 141, 143 (e.g., source and gate) of the first power semiconductor 140 forms an electrical connection with the first metal layer 113 at the first laminate upper main face 111 by one or more microvias 115 extending through the first laminate layer 110.

Similarly, the second semiconductor lower main face is coplanar arranged with the fourth laminate lower main face 122 to form an electrical connection between the second terminal 152 (e.g., drain) of the second power semiconductor 150 and the fourth metal layer 124 at the second laminate lower main face 122. The at least one first terminal 151, 153 (e.g., source and gate) of the second power semiconductor 150 forms an electrical connection with the third metal layer 123 at the second laminate upper main face 121 by one or more microvias 125 extending through the second laminate layer 120.

FIG. 2C shows a schematic cross section of a semiconductor power entity 100c according to a third embodiment.

This third embodiment is similar to the first embodiment, but the first power semiconductor 140 is directly placed below and connected to the first metal layer 113 without applying vias in between. Similarly, the second power semiconductor 150 is directly placed on and connected to the fourth metal layer 124 without applying vias in between. In this third embodiment, a direct electrical and thermal path is implemented to outer surface of the power entity. This third embodiment is beneficial for heat extraction to external heatsink because the main thermal path has no microvias. It is further beneficial for lowest stray inductance for half-bridge configurations, where MOSFET 1 (140) is the low side switch and MOSFET 2 (150) is the high-side switch.

In this third embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor upper main face is coplanar arranged with the first laminate upper main face 111 to form an electrical connection between the at least one first terminal 141, 143 (e.g., source and gate) of the first power semiconductor 140 and the first metal layer 113 at the first laminate upper main face 111. The second terminal 142 (e.g., drain) of the first power semiconductor 140 forms an electrical connection with the second metal layer 114 at the first laminate lower main face 112 by one or more microvias 116 extending through the first laminate layer 110.

Similarly, the second semiconductor lower main face is coplanar arranged with the fourth laminate lower main face 122 to form an electrical connection between the second terminal 152 (e.g., drain) of the second power semiconductor 150 and the fourth metal layer 124 at the second laminate lower main face 122. The at least one first terminal 151, 153 (e.g., source and gate) of the second power semiconductor 150 forms an electrical connection with the third metal layer 123 at the second laminate upper main face 121 by one or more microvias 125 extending through the second laminate layer 120.

FIG. 2D shows a schematic cross section of a semiconductor power entity 100d according to a fourth embodiment. In this fourth embodiment, the shortest possible direct chip-to-chip connection can be implemented. This fourth embodiment is beneficial for lowest chip-to-chip connection impedance.

This fourth embodiment is similar to the first embodiment, but the first power semiconductor 140 is directly placed on the second metal layer 114 without applying vias. Similarly, the second power semiconductor 150 is directly placed below the third metal layer 123 without applying vias.

In this fourth embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor lower main face is coplanar arranged with the first laminate lower main face 112 to form an electrical connection between the second terminal 142 of the first power semiconductor 140 and the second metal layer 114 at the first laminate lower main face 112. The at least one first terminal 141, 143 (e.g., source and gate) of the first power semiconductor 140 forms an electrical connection with the first metal layer 113 at the first laminate upper main face 111 by one or more microvias 115 extending through the first laminate layer 110.

Similarly, the second semiconductor upper main face is coplanar arranged with the second laminate upper main face 121 to form an electrical connection between the at least one first terminal 151, 153 (e.g., source and gate) of the second power semiconductor 150 and the third metal layer 123 at the second laminate upper main face 121. The at second terminal 152 (e.g., drain) of the second power semiconductor 150 forms an electrical connection with the fourth metal layer 124 at the second laminate lower main face 122 by one or more microvias 125 extending through the second laminate layer 120.

FIG. 2E shows a schematic cross section of a semiconductor power entity 100e according to a fifth embodiment. In this fifth embodiment, a direct electrical and thermal path of upper power semiconductor 140 to outer surface of power entity can be implemented. This fifth embodiment can be used for the implementation of a low side switch of a half-bridge configuration which has direct electrical and thermal path to outer surface of power entity.

This fifth embodiment is similar to the first embodiment, but the first power semiconductor 140 is directly placed below the first metal layer 113 without applying vias. Similarly, the second power semiconductor 150 is directly placed below the third metal layer 123 without applying vias.

In this fifth embodiment, the first power semiconductor 140 has a first semiconductor upper main face and a first semiconductor lower main face opposing the first semiconductor upper main face. The second power semiconductor 150 has a second semiconductor upper main face and a second semiconductor lower main face opposing the second semiconductor upper main face.

The first semiconductor upper main face is coplanar arranged with the first laminate upper main face 111 to form an electrical connection between the at least one first terminal 141, 143 (e.g., source and gate) of the first power semiconductor 140 and the first metal layer 113 at the first laminate upper main face 111. The second terminal 142 (e.g., drain) of the first power semiconductor 140 forms an electrical connection with the second metal layer 114 at the first laminate lower main face 112 by one or more microvias 116 extending through the first laminate layer 110.

Similarly, the second semiconductor upper main face is coplanar arranged with the second laminate upper main face 121 to form an electrical connection between the at least one first terminal 151, 153 (e.g., source and gate) of the second power semiconductor 150 and the third metal layer 123 at the second laminate upper main face 121. The second terminal 152 (e.g., drain) of the second power semiconductor 150 forms an electrical connection with the fourth metal layer 124 at the second laminate lower main face 122 by one or more microvias 125 extending through the second laminate layer 120.

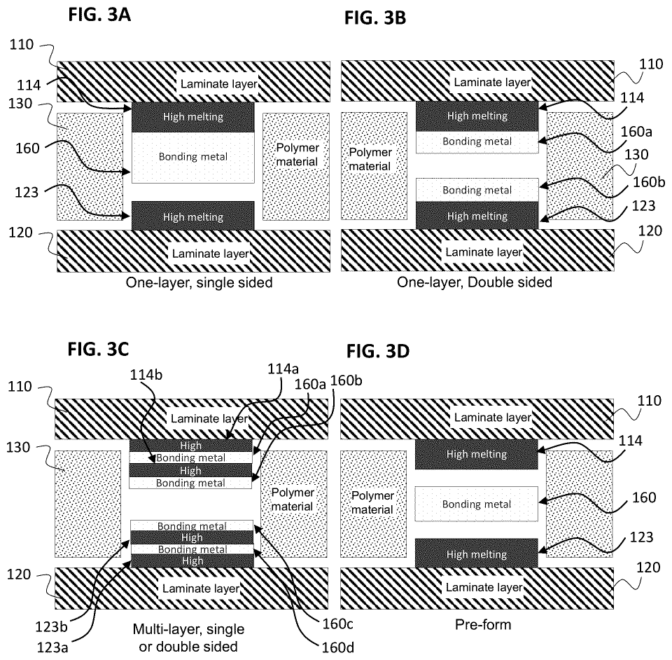

FIGS. 3A-3D shows different options for producing the metal stack for panel level hybrid bonding according to the embodiments. FIGS. 3A-3D shows metal stack options for panel level hybrid bonding. The low melting metal can also be applied as paste for sintering or diffusion soldering. The polymer material can be a sheet material, printed, dispensed or pre-laminated.

FIG. 3A shows one-layer, single sided as a first option. FIG. 3B shows one-layer, double sided as a second option. FIG. 3C shows multi-layer, single or double sided as a third option. FIG. 3D shows pre-form as a fourth option. Although the picture was originally intended for slid bonding, it can also be applied to sintering and hybrid bonding according to the embodiments.

In FIGS. 3A to 3D, a semiconductor power entity is illustrated including a first laminate layer 110, also referred to as a first substrate, having a first laminate upper main face 111 and a first laminate lower main face 112 opposing the first laminate upper main face 111, e.g., as illustrated in FIGS. 2A to 2E; a second laminate layer 120 having a second laminate upper main face 121 and a second laminate lower main face 122 opposing the second laminate upper main face 121, e.g., as illustrated in FIGS. 2A to 2E.

The semiconductor power entity includes an isolation layer 130, e.g., made of polymer material, arranged between the first laminate layer 110 and the second laminate layer 120, where the isolation layer 130 can be either arranged in between the laminate layers 110, 120 during stack-up or be attached/applied to either but not both of the laminate layers 110, 120 facing main faces before stack-up.

The semiconductor power entity may include a first metal layer 113 arranged at the first laminate upper main face 111 of the first laminate layer 110 (not shown in FIGS. 3A to 3D) and a fourth metal layer 124 arranged at the second laminate lower main face 122 of the second laminate layer 120 (not shown in FIGS. 3A to 3D).

The semiconductor power entity of FIG. 3A includes a second metal layer 114 arranged at the first laminate lower main face 112 of the first laminate layer 110 and a third metal layer 123 arranged at the second laminate upper main face 121 of the second laminate layer 120. As shown in FIG. 3A, these can be single metal layers 114, 123 made of high melting material.

The semiconductor power entity of FIG. 3A includes a connection metal layer 160 embedded in the isolation layer 130 between the first laminate layer 110 and the second laminate layer 120, the connection metal layer 160 forming an electrical connection with the second metal layer 114 and the third metal layer 123 after lamination. The connection metal layer 160 can be a single layer made of bonding metal attached to the second metal layer 114 of high melting material as illustrated in FIG. 3A.

The semiconductor power entity of FIG. 3B is similar to FIG. 3A, however, the connection metal layer 160 is made of two parts 160a and 160b of bonding metal which are attached to the respective second metal layer 114 and third metal layer 123 made of high melting material.

The semiconductor power entity of FIG. 3C is similar to FIG. 3A, however, the second metal layer 114, the third metal layer 123 and the connection metal layer 160 are implemented as a first multi-layer which is formed of respective portions 114a, 114b of the second metal layer arranged alternately with respective portions 160a, 160b of the connection metal layer; and a second multi-layer which is formed of respective portions 123a, 123b of the third metal layer arranged alternately with respective portions 160c, 160d of the connection metal layer.

This provides at least the advantage that the diffusion length of the metals to form the stable IMC can be shortened significantly. This results in a reduction of the metal bonding time from a few hours to a few minutes and can dramatically increase production throughput.

The multilayer structure of the bond metal also provides additional degrees of freedom to control the kinetics of the metal bonding. In order to achieve a void-free metal bond it can be necessary to form the metal bond significantly faster or slower relative to the kinetics of the dielectric bond.

The semiconductor power entity of FIG. 3D is similar to FIG. 3A, however, the connection metal layer 160 is made of a pre-form of bonding metal applied between the second metal layer 114 and the third metal layer 123 made of high melting material.

In the semiconductor power entities shown in FIGS. 3A to 3D, the different metal stack options for panel level hybrid bonding are illustrated. The bonding metal can also be applied as paste for sintering or diffusion soldering. The polymer material can be a sheet material, printed, dispensed or pre-laminated or any other suitable form.

The embodiments shown in FIGS. 3A to 3D can be implemented by the different bond material combinations, metal stack options and process options as illustrated in Table 1. Some important combinations are described as embodiments, i.e., the embodiments shown in FIGS. 3A, 3B, 3C and 3D, where low melting material is denoted as bonding metal.

TABLE 1
Example of possible metal systems for low temperature joining. Columns:
High temperature melting metals; Rows: Low temperature melting metals
and sinter materials. The cell content denotes the type of non-remelting
metal joint that can be formed by that combination: Either “Diff.
sold.” = diffusion soldering (SLID, TLPB) or “Sinter” = sintering.

| | | Contact metals/High meltingpoint metals | | | | |
|---|---|---|---|---|---|---|
| Bond metals | | Cu | Ni | Au | Pd | Ag |
| Low melting | Sn | Diff. sold. | Diff. sold. | Diff. sold. | Diff. sold. | Diff. sold. |
| point metals | In | Diff. sold. | Diff. sold. | Diff. sold. | Diff. sold. | Diff. sold. |
| | Sn:In | Diff. sold. | Diff. sold. | Diff. sold. | Diff. sold. | Diff. sold. |
| | Sn:Ag | Diff. sold. | Diff. sold. | Diff. sold. | Diff. sold. | Diff. sold. |
| Sinter material | Ag paste | Sinter | — | Sinter | Sinter | Sinter |
| | Cu paste | Sinter | — | Sinter | Sinter | Sinter |
| | Ag filaments | Sinter | Sinter | Sinter | Sinter | Sinter |
| | Cu filaments | Sinter | Sinter | Sinter | Sinter | Sinter |

Table 1 is non-exhaustive. It lists the most practical and best available metal combinations. It can be understood that this table 1 is just an example, does not limit the embodiments to these combinations. All other suitable low temperature diffusion solder metal combinations and all other low temperature sinter metals and particle shapes may be applied as well.

The following metals and bonding layer options may exist inter alia (see Table 1):
1) The high temperature melting metal can be one layer structure (e.g., Cu. Ni) or multilayer structure (e.g., Cu+Au, Cu+Ni, Ni+Au, Cu+Ni+Au).
2) The low temperature melting metal can be Sn, In or some other suitable metal, metal alloy or combination of several metals e.g., SnAg, InSn.
3) The bonding layer can be liquid or film type polymer material e.g., epoxy, epoxy mixture, BT epoxy, PI or other type of polymer that is compatible with laminate materials or ABF (Ajinomoto build-up film) or RCC (resin coated copper).
4) The bonding material can be uncured, precured or semicured.

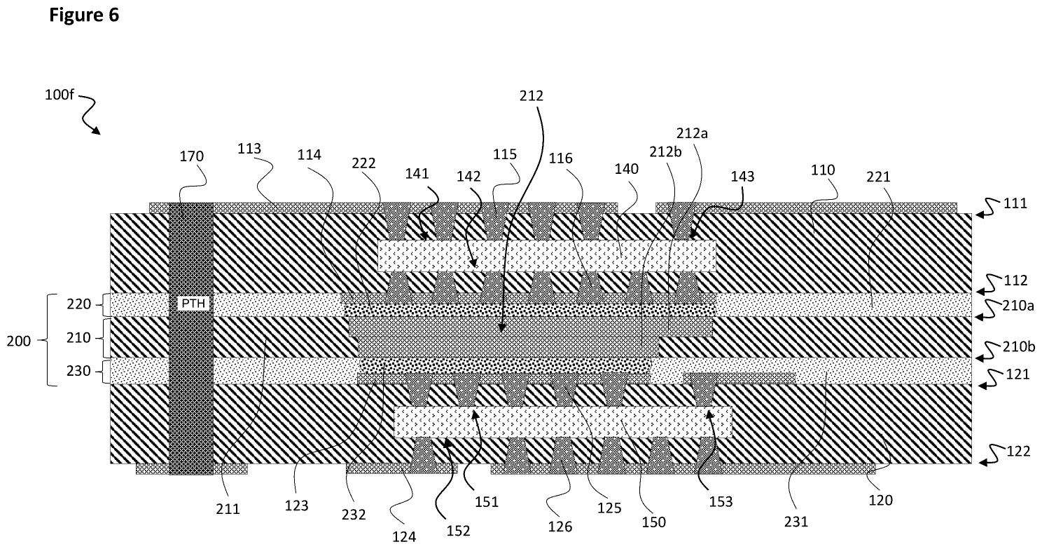

The following metal stack options are illustrated in FIGS. 3A to 3D:
a) The low melting and high melting metals on laminate can be a simple one-layer structure or printed paste on only one laminate layer (high melting metal+low temperate metal/metal alloy stack), see FIG. 3A.
b) The low melting and high melting metals on laminate can be a simple one layer structure or printed paste on both laminate layers (high melting metal+low temperate metal/metal alloy stack), see FIG. 3B.
c) The low melting and high melting metals on laminate can be a multilayer sandwich or other type of structure on one or both laminate layers (high+low+high+low . . . ), see FIG. 3C.
d) The low melting temperate metal or metal alloy or metal paste can be in a separate preform that is placed between the laminates, see FIG. 3D.
e) The bond materials can be supplied on a bond sheet/carrier sheet, e.g., the hybrid bond sheet according to the embodiments, that is placed in between the laminates, see FIG. 6.

The following process/step options can be applied:
1) The low temperature metal or metal alloy or metal paste layer and/or polymer bonding layer is on one or two sides of the laminate.
2) The low temperature metal or metal alloy or metal compound layer is on one or two sides of the laminate and the polymer bonding layer is brought in-between in a separate step.
3) The polymer bonding layer is on one or two sides of the laminate and the low temperature metal or metal alloy or metal paste preform is brought in-between in a separate step.
4) The polymer bonding layer and the low temperature metal or metal alloy or metal paste preform are brought in-between the laminates during the lay-up process.
5) The pre-manufactured hybrid bond sheet is brought in between the laminates during the lay-up process.

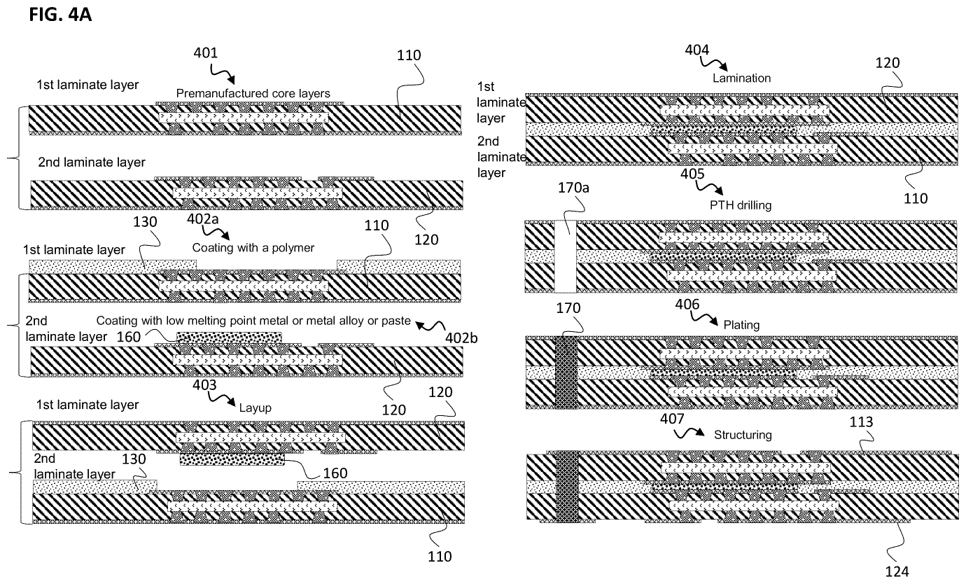

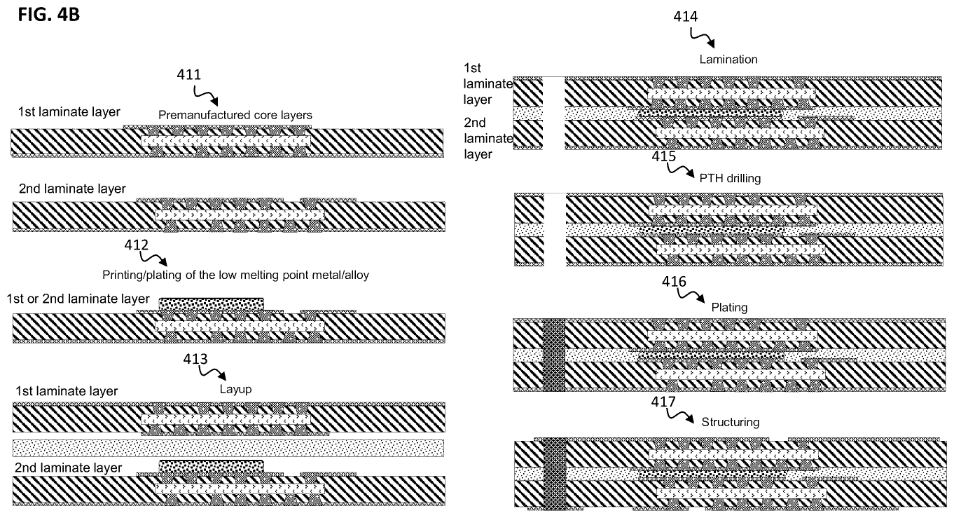

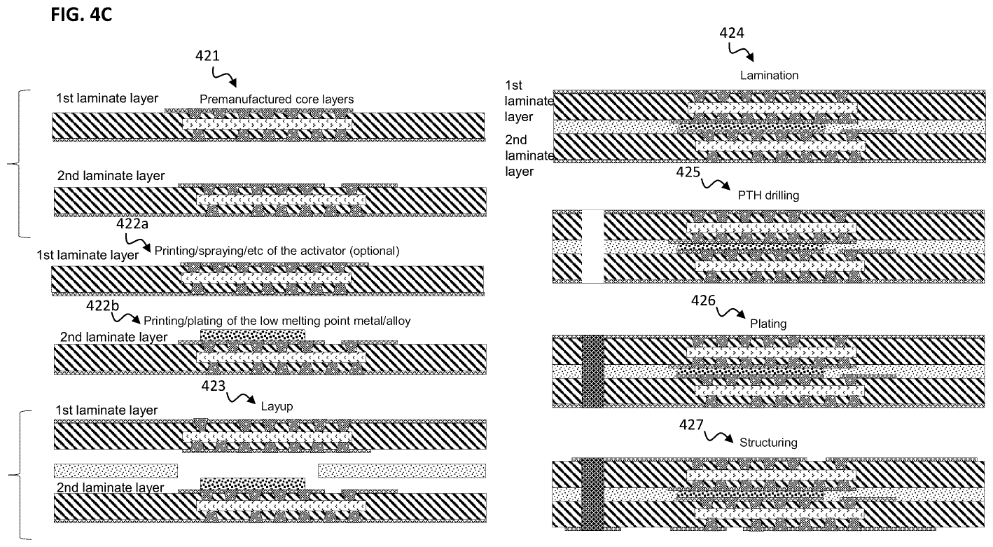

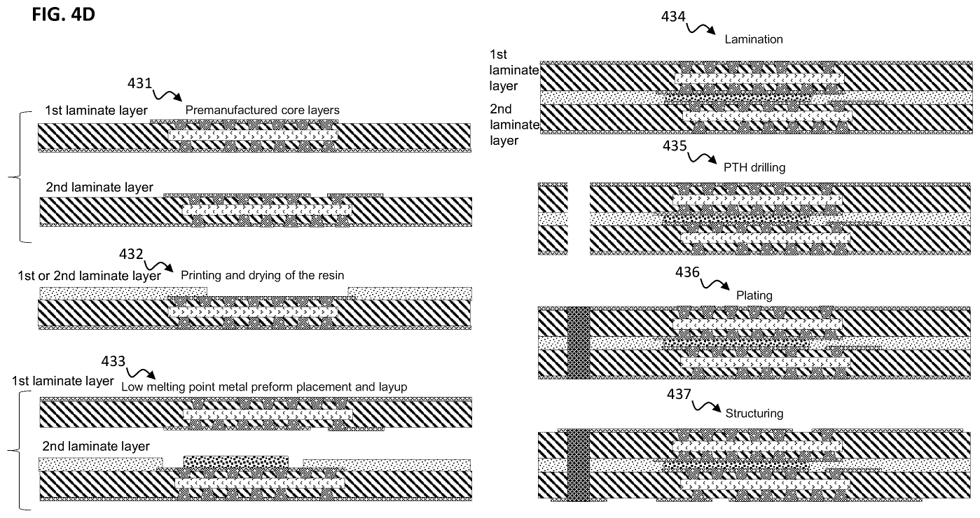

The different process flow options are described below with respect to FIGS. 4A, 4B, 4C and 4D. The different options for the hybrid bond sheet are shown in FIGS. 6 to 9. In addition to the described process flows, also combination of modifications from the described options can be used.

FIG. 4A shows a process flow diagram of a method for producing a semiconductor power entity according to a first embodiment referring to resin printing.

This process option 1-resin printing-describes a process where the polymer bonding material is printed, coated, laminated; dispensed, etc. on one (or two) laminate layers and the bonding metal is plated, printed, dispensed on one (or two) laminate layers before the bonding. In option 1-resin printing, the polymer bonding material and the bonding metal are applied on one or two laminate layers before the bonding.

In a first step, two premanufactured laminate layers, also referred to as core layers or laminate core layers, are provided 401 which are printed with the polymer bonding material. The two premanufactured laminate layers may correspond to the first laminate layer 110 and the second laminate layer 120 described above with respect to FIGS. 2A to 2E.

In a second step, the first premanufactured laminate layer 110 is coated 402a with the polymer bonding material and the second premanufactured laminate layer 120 is coated 402b with low melting point metal or metal alloy or paste.

In a third step, the second premanufactured laminate layer 120 is turned around and arranged above the first premanufactured laminate layer 110 to provide a layup 403

In a fourth step, the layup 403 is laminated 404 to provide a semiconductor power product.

In a fifth step, one or more holes are drilled 405 in the semiconductor power product.

In a sixth step, the one or more holes are plated 406 by a conductive metal layer

In a seventh step, the semiconductor power product is structured 407, e.g., by structuring the first metal layer 113 and the fourth metal layer 124.

If no holes 170 are used at this phase, the metal layer can also be structured in an earlier phase and this seventh step is not needed. This applies as well to all other process options 2 to 4 described below.

Depending on the design and application, the above-described fifth, sixth, and seventh steps are optional and can be applied as well to all other process options 2 to 4 described below.

FIG. 4B shows a process flow diagram of a method for producing a semiconductor power entity according to a second embodiment referring to non-structured resin sheet.

This process option 2-non-structured resin sheet-describes a process where the bonding metal is plated, printed, dispensed on one (or two) laminate layers before the bonding and the non-structured polymer material is placed between the laminate layers during layup and lamination process. In option 2-non-structured resin sheet, the bonding metal is applied on one or two laminate layers before the bonding and the non-structured polymer material is placed between the laminate layers during lay-up and lamination.

In a first step, two premanufactured laminate layers 411 are provided that may correspond to the first laminate layer 110 and second laminate layer 120 described above with respect to FIGS. 2A to 2E.

In a second step one of the premanufactured laminate layers is printed or plated 412 with low melting point metal or metal alloy.

In a third step, a layup 413 is provided of the first and second premanufactured laminate layers and a polymer layer in between.

In a fourth step, the layup 403 is laminated 414 to provide a semiconductor power product.

In a fifth step, one or more holes are drilled 415 in the semiconductor power product.

In a sixth step, the one or more holes are plated 416 by a conductive metal layer.

In a seventh step, the semiconductor power product is structured 417, e.g., by structuring the first metal layer 113 and the fourth metal layer 124.

If no holes 170 are used at this phase, the metal layer can also be structured in an earlier phase and this seventh step is not needed. Depending on the design and application, the above-described fifth, sixth, and seventh steps are optional.

FIG. 4C shows a process flow diagram of a method for producing a semiconductor power entity according to a third embodiment referring to structured prepreg or resin sheet.

This process option 3-structured prepreg or resin sheet-describes a process where the bonding metal is plated, printed, dispensed on one (or two) laminate layers before the bonding and the structured polymer material is placed between the laminate layers during layup and lamination process. In option 3-structured prepreg or resin sheet, the bonding metal is applied on one or two laminate layers before the bonding and the structured polymer material is placed between the laminate layers during layup and lamination process.

In a first step, two premanufactured laminate layers 421 are provided that may correspond to the first laminate layer 110 and second laminate layer 120 described above with respect to FIGS. 2A to 2E.

In a second step, activator material is printed, sprayed, etc. 422a on the first premanufactured laminate layer and the premanufactured second laminate layer is printed or plated 422b with low melting point metal or metal alloy.

In a third step 423, a layup 423 is provided of the first and second premanufactured laminate layers and a structured polymer layer in between.

In a fourth step, the layup 423 is laminated 424 to provide a semiconductor power product.

In a fifth step, one or more holes are drilled 425 in the semiconductor power product.

In a sixth step, the one or more holes are plated 426 by a conductive metal layer

In a seventh step, the semiconductor power product is structured 427, e.g., by structuring the first metal layer 113 and the fourth metal layer 124.

If no holes 170 are used at this phase, the metal layer can also be structured in an earlier phase and this seventh step is not needed. Depending on the design and application, the above-described fifth, sixth, and seventh steps are optional.

FIG. 4D shows a process flow diagram of a method for producing a semiconductor power entity according to a fourth embodiment referring to preform placement. In preform placement, the polymer bonding material is applied on one or two laminate layers and the bonding metal preform is placed, e.g., by pick and placement process, on the copper pad of the lower laminate layer before the bonding.

This process option 4-preform placement-describes a process where the polymer bonding material is printed, coated, laminated, dispensed, etc. on one (or two) laminate layers and the bonding metal preform is placed (e.g., pick and placement process) on copper pad on lover laminate layers before the bonding before the bonding.

In a first step, two premanufactured laminate layers 431 are provided that may correspond to the first laminate layer 110 and second laminate layer 120 described above with respect to FIGS. 2A to 2E.

In a second step, one of the two premanufactured laminate layers 431 is printed with resin and the resign is dried 432

In a third step, a low melting point metal preform is placed on the resign printed premanufactured laminate layer and a layup 433 is provided together with the other premanufactured laminate layer.

In a fourth step, the layup 423 is laminated 434 to provide a semiconductor power product.

In a fifth step, one or more holes are drilled 435 in the semiconductor power product.

In a sixth step, the one or more holes are plated 436 by a conductive metal layer

In a seventh step, the semiconductor power product is structured 437, e.g., by structuring the first metal layer 113 and the fourth metal layer 124.

If no holes 170 are used at this phase, the metal layer can also be structured in an earlier phase and this seventh step is not needed. Depending on the design and application, the above-described fifth, sixth, and seventh steps are optional.

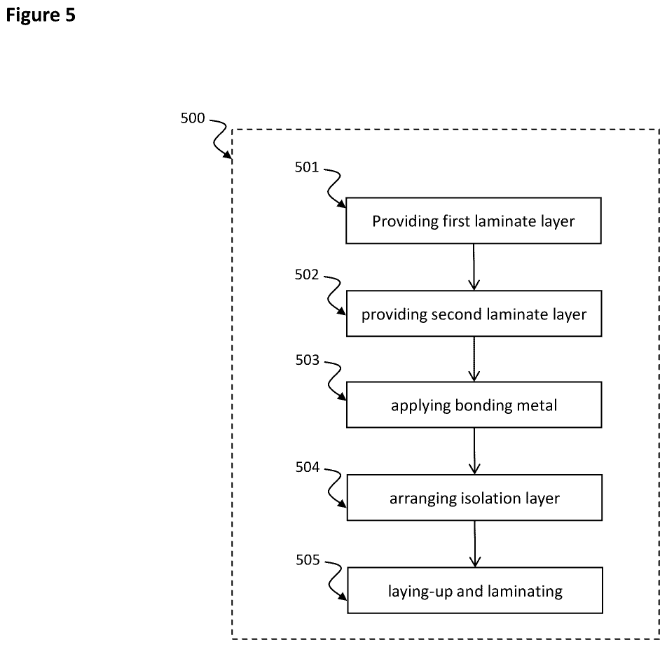

FIG. 5 shows a schematic diagram illustrating a method 500 for producing a semiconductor power entity according to the embodiments.

The semiconductor power entity can be a semiconductor power entity 100, 100b, 100c, 100d, 100e as described above with respect to FIGS. 2A to 2E.

The method 500 includes providing 501 a first laminate layer 110 embedding a first power semiconductor 140, the first laminate layer 110 having a first laminate upper main face 111 and a first laminate lower main face 112 opposing the first laminate upper main face 111, where a first metal layer 113 is arranged at the first laminate upper main face 111 of the first laminate layer 110 and a second metal layer 114 is arranged at the first laminate lower main face 112 of the first laminate layer 110, e.g., as described above with respect to FIGS. 2A to 2E.

The method 500 includes providing 502 a second laminate layer 120 embedding a second power semiconductor 150, the second laminate layer 120 having a second laminate upper main face 121 and a second laminate lower main face 122 opposing the second laminate upper main face 121, where a third metal layer 123 is arranged at the second laminate upper main face 121 of the second laminate layer 120 and a fourth metal layer 124 is arranged at the second laminate lower main face 122 of the second laminate layer 120, e.g., as described above with respect to FIGS. 2A to 2E.

The method 500 includes applying 503 a bonding metal at the second metal layer 114 of the first laminate layer 110 and/or the third metal layer 123 of the second laminate layer 120, the bonding metal being placed between the first power semiconductor 140 and the second power semiconductor 150 and/or between respective electrical contact pairs in the first laminate layer and the second laminate layer, e.g., as described above with respect to FIGS. 2A to 2E.

The method 500 includes arranging 504 an isolation layer 130 between the second metal layer 114 of the first laminate layer 110 and the third metal layer 123 of the second laminate layer 120, e.g., as described above with respect to FIGS. 2A to 2E.

The method 500 includes laying-up and laminating 505 the first laminate layer 110, the second laminate layer 120 and the isolation layer 130 to a semiconductor power entity 100, where the laminating transforms the bonding metal to a connection metal layer 160 forming an electrical connection with the second metal layer 114 and the third metal layer 123, e.g., as described above with respect to FIGS. 2A to 2E or with respect to FIGS. 4A to 4D.

The connection metal layer 160 may be formed simultaneously with the lamination of the first laminate layer 110, the second laminate layer 120 and the isolation layer 130.

The method 500 may further include: applying 503 the bonding metal at the second metal layer 114 of the first laminate layer 110 before the laying-up and laminating 505; and applying the isolation layer 130 at the third metal layer 123 of the second laminate layer 120 before the laying-up and laminating 505, where the isolation layer 130 is structured to form an opening for embedding the bonding metal, e.g., as shown in FIG. 4A.

Applying 503 the bonding metal may include plating, printing or dispending; and applying the isolation layer 130 may include printing, coating, laminating or dispensing, e.g., as shown in FIG. 4A.

The method 500 may further include: applying the isolation layer 130 at the third metal layer 123 of the second laminate layer 120 before the laying-up and laminating 505, where the isolation layer 130 is structured to form an opening for embedding the bonding metal; and placing the bonding metal into the opening of the isolation layer 130 on the third metal layer 123, e.g., as shown in FIG. 4D.

The method 500 may further include: placing the isolation layer 130 between the second metal layer 114 of the first laminate layer 110 and the third metal layer 123 of the second laminate layer 120 during the laying-up and laminating 505, where the isolation layer 130 is non-structured, e.g., as shown in FIG. 4B.

The method 500 may further include: placing the isolation layer 130 between the second metal layer 114 of the first laminate layer 110 and the third metal layer 123 of the second laminate layer 120 during the laying-up and laminating, where the isolation layer 130 is structured to form an opening for embedding the bonding metal, e.g., as shown in FIG. 4C.

The following process steps of the method 500 are optional: drilling holes in the semiconductor power entity 100 extending from the first metal layer 113 to the fourth metal layer 124, where the holes are drilled laterally to the first and second power semiconductors 140, 150; metal plating the holes to form metal plated through holes electrically connecting the first metal layer 113 with the fourth metal layer 124; and structuring the first metal layer 113 and the fourth metal layer 124.

FIG. 6 shows a schematic cross section of a semiconductor power entity 100f with a hybrid bond sheet 200 according to the embodiments.

The hybrid bond sheet 200 can be used for bonding a first joining member 110 to a second joining member 120.

The hybrid bond sheet 200 includes a core layer 210, a first bonding layer 220 and a second bonding layer 230.

The core layer 210 has an upper main face 210a and a lower main face 210b opposing the upper main face 210a, as shown in FIG. 6. The core layer 210 includes a core insulating layer 211 formed between the upper main face 210a and the lower main face 210b; and one or more metallic through-connections 212 penetrating the core insulating layer 211 from the upper main face 210a to the lower main face 210b. These through-connections 212 can be stacked upon each other, as illustrated in FIG. 6 or placed side-by-side (not shown in FIG. 6).

The first bonding layer 220 is used for bonding the first joining member 110. The first bonding layer 220 is formed at the upper main face 210a of the core layer 210. The first bonding layer 220 includes a first insulating bond layer 221 formed on the core insulating layer 211 and a first metal bond layer 222 formed on the one or more metallic through-connections 212.

The second bonding layer 230 is used for bonding the second joining member 120. The second bonding layer 230 is formed at the lower main face 210b of the core layer 210. The second bonding layer 230 includes a second insulating bond layer 231 formed on the core insulating layer 211 and a second metal bond layer 232 formed on the one or more metallic through-connections 212.

The one or more metallic through-connections 212 and the first and second metal bond layers 222, 232 are configured to form an electrically and thermally conductive connection with the first joining member 110 and the second joining member 120, as shown in FIG. 6.

In the embodiments, hybrid bond sheet means that bonding of the 2 joining members 110, 120 includes more than one (here: 2) bonding mechanisms, an electrically conductive metallurgical bond, and a dielectric, electrically isolating bond. The two bond mechanisms act in laterally separated partial areas of the bond sheet, which is brought in between the 2 joining partners.

The hybrid bond sheet presented in the embodiments can be used as a thermal management sheet.

The first joining member 110 and/or the second joining member 120 may include at least one or a combination of a laminate layer, a mold layer, a metal-structured laminate or mold layer, an embedded component layer, a redistribution metallization layer, and an interposer layer. The example of metal-structured laminate layers for both joining members 110, 120 is shown in FIG. 6.

The core insulating layer 211 may include at least one or a combination of the following: a printed circuit board laminate, a mold sheet, an Ajinomoto build-up film (ABF), a molded interconnect substrate (MIS), a polymer composite material, and a polymer sheet material.

The one or more metallic through-connections 212 may include at least one or a combination of the following components: metal vias, metal bars, metal spacers, metal studs, metal bumps, and metal balls.

In the example of FIG. 6, the one or more metallic through-connections 212 may include a first part 212a being formed at the upper main face 210a of the core layer 210, and a second part 212b being formed at the lower main face 210b of the core layer 210.

It can be understood that the one or more metallic through-connections 212 are not restricted to have two parts, they can also include 3, 4, 5, and more parts or even only one part. These parts can be stacked upon each other and/or placed side-by-side or any combination thereof.

In specific applications, the first part 212a and the second part 212b can be shaped differently.

The first part 212a can be broader than the second part 212b as shown in FIG. 6, or the first part 212a can have the same shape as the second part 212b or the first part can be smaller than the second part 212b.

The one or more metallic through-connections 212 can be fully metallized non-sectioned through-connections 212, as shown in FIG. 6. Alternatively, the one or more metallic through-connections 212 can be partially metallized and/or sectioned through-connections 212.

In the embodiments, fully metallized means made of full metal, i.e., not sectioned into first/second part, cross-section does not change in z direction (from bottom to top of FIG. 6), or 1^{st}/2^{nd} part shaped equally. Reason for the sectioning is clearance of conductor traces when there are two metal areas that should be isolated, but one of them should have higher current capability.

Another reason for the sectioning is adhesion and stability of the mold sheet. The inner surface is increased by the step, the metal part is better locked into the core layer, providing higher stability during handling of the sheet in production.

The one or more metallic through-connections 212 may include at least two fully metallized non-sectioned through-connections 212 of any shape.

The joining members 110, 120 can be functional layers, each one including an outer metallization 114, 123. One or both of the first metal bond layer 222 and the second metal bond layer 232 can form a non-remelting electrical and mechanical connection with the outer metallization 114, 123 of the joining members 110, 120.

The joining members 110, 120 can be functional layers, each one including an outer metallization 114, 123. One or both of the first metal bond layer 222 and the second metal bond layer 232 can form one of a diffusion soldering connection, a sintering connection or a nano-hair Velcro bonding connection with the outer metallization 114, 123 of the joining members 110, 120.

The first insulating bond layer 221 and the second insulating bond layer 231 can form an electrically isolating bond connection between the joining members 110, 120.

The electrically isolating bond connection provides dielectric breakdown strength, mechanical stability, protection, and insulation against moisture and contamination of the interface between the joining partners.

The one or more metallic through-connections 212 may be arranged in a predetermined pattern that is aligned with a structure of the first joining member 110 and/or the second joining member 120.

This defines the product-specific contact scheme. The bond sheets are uniquely designed to match exactly their respective joining partner surfaces.

The one or more metallic through-connections 212 may be arranged in a predetermined pattern having a uniform structure to support a universal contact scheme for different products and/or applications.

This defines the universal contact scheme with a repetitive raster-like pattern that matches many products.

The first insulating bond layer 221 and/or the second insulating bond layer 231 can be made of thermosetting material.

The hybrid bond sheet 200 shown in FIG. 6 can be applied in a semiconductor power entity 100f as illustrated in FIG. 6.

Such a semiconductor power entity 100f includes a first joining member 110, a second joining member 120, and the hybrid bond sheet 200.

The first joining member 110 has a first upper main face 111 and a first lower main face 112 opposing the first upper main face 111. The first joining member 110 includes a first metal layer 113 arranged at the first upper main face 111 and a second metal layer 114 arranged at the first lower main face 112.

The second joining member 120 has a second upper main face 121 and a second lower main face 122 opposing the second upper main face 121. The second joining member 120 includes a third metal layer 123 arranged at the second upper main face 121 and a fourth metal layer 124 arranged at the second lower main face 122.

The hybrid bond sheet 200 as described above is formed between the first joining member 110 and the second joining member 120.

The one or more metallic through-connections 212 and the first and second metal bond layers 222, 232 of the hybrid bond sheet 200 form an electrically and thermally conductive connection with the second metal layer 114 and the third metal layer 123 of the first joining member 110 and the second joining member 120.

The first insulating bond layer 221 and the second insulating bond layer 231 of the hybrid bond sheet 200 form an electrically isolating bond connection between the joining members 110, 120.

The isolating bond connection provides dielectric breakdown strength, mechanical stability, protection, and insulation against moisture and contamination of the interface between the joining partners.

The first joining member 110 may embed a first power semiconductor 140; and/or the second joining member 120 may embed a second power semiconductor 150 as shown in the example of FIG. 6.

The one or more metallic through-connections 212 and the first and second metal bond layers 222, 232 of the hybrid bond sheet 200 may form a direct electrical connection path between the first power semiconductor 140 and the second power semiconductor 150 without a detour via through-hole vias arranged laterally to the two power semiconductors 140, 150.

The semiconductor power entity 100f shown in FIG. 6 can be produced by the following method:

This method includes the following:

Providing a first joining member 110 embedding a first power semiconductor 140, the first joining member 110 having a first upper main face 111 and a first lower main face 112 opposing the first upper main face 111; where a first metal layer 113 is arranged at the first upper main face 111 of the first joining member 110 and a second metal layer 114 is arranged at the first lower main face 112 of the first joining member 110;

Providing a second joining member 120 embedding a second power semiconductor 150, the second joining member 120 having a second upper main face 121 and a second lower main face 122 opposing the second upper main face 121; where a third metal layer 123 is arranged at the second upper main face 121 of the second joining member 120 and a fourth metal layer 124 is arranged at the second lower main face 122 of the second joining member 120;

Forming a hybrid bond sheet 200 according to the above description between the first joining member 110 and the second joining member 120 and laying-up the first joining member 110, the second joining member 120 and the hybrid bond sheet 200; and

Laminating the layed-up first joining member 110, second joining member 120 and hybrid bond sheet 200 to a semiconductor power entity 100f, where the laminating transforms the one or more metallic through-connections 212 and the first and second metal bond layers 222, 232 of the hybrid bond sheet 200 to form an electrically and thermally conductive connection with the second metal layer 114 and the third metal layer 123 of the first joining member 110 and the second joining member 120; and where the laminating cures the insulating bond layers 221, 231 of the hybrid bond sheet 200 to form an electrically isolating bond connection between the joining members 110, 120.

The laminating may simultaneously cure the isolating bond layers bonding together all surfaces in contact and embedding/encapsulating the joined metal layers.

In the following Figures, embodiments or process options of the hybrid bond sheet are described.

The common structure for the hybrid bond sheet as described in embodiments (or process options) 5 to 8 includes a carrier sheet (core layer 210) that can be manufactured, e.g., from PCB laminate material, or other type of polymer sheet material and the bonding layers 220, 230 that are on both sides of the core layer 210. The core layer 210 may include a polymer matrix 211, with or without glass fiber reinforcement, and vertical through-connections 212 (e.g., Cu vias or Cu bars or Cu spacers) that are embedded inside the polymer matrix 211 and exposed from both sides. The vertical through-connections 212 (e.g., Cu vias, Cu bars or Cu spacers) can be manufactured with several different kinds of processes (e.g., drilling and plating, pre-plating on a carrier and laminating inside the core, preforming, placing and laminating inside the core, etc.). On both sides of the core layer 210 can be polymer based bonding material 221, 231 and metallic bonding material 222, 232, that are forming the metallic and isolating connection between laminated layers.

The sheet 200 can have more than one any-shape full metal vertical through-connections extending from top face to bottom face. Possible sizes range from 50 μm x/y dimensions to 5 mm xy dimensions, and a thickness range of 20 to 500 μm. In a possible extreme case maybe even up to 2 mm thickness for heat spreading purposes. The full metal cross-section can provide a highest possible electrical and thermal conductivity.

The through-connection shape can be optimized for different purposes: Increased anchoring/interlocking between polymer and metal within the sheet. This can allow large and thick vertical connection geometries. Rounded corner shapes can improve breakdown behavior, etc.

The bond materials can be applied to the carrier sheet surface or carrier topology. They can be based on a group of technologies: diffusion soldering (SLID, TLBS), sintering, and nano-hair Velcro bonding. They can be combined with a polymeric dielectric bond material, which fills the area around the vertical connection contacts.

The resulting bond connection can be of a non-remelting type, which means that it will not remelt or get soft during subsequent production steps or during assembly, even if they reach or exceed the bond temperature.

The hybrid bond sheet can be used to thermally enhance cooling and enable cooling from both sides of the laminated and integrated boards. The boards can have at least a fraction of flat surfaces on both main faces, which can be used to directly connect a heatsink by soldering, sintering, glueing, or by electrically isolating TIM.

The laminate layer circuit technologies can have different requirements with respect to contact density, e.g., one can be a HDI PCB, the other one a power PCB with high current copper inlays and embedded power switches.

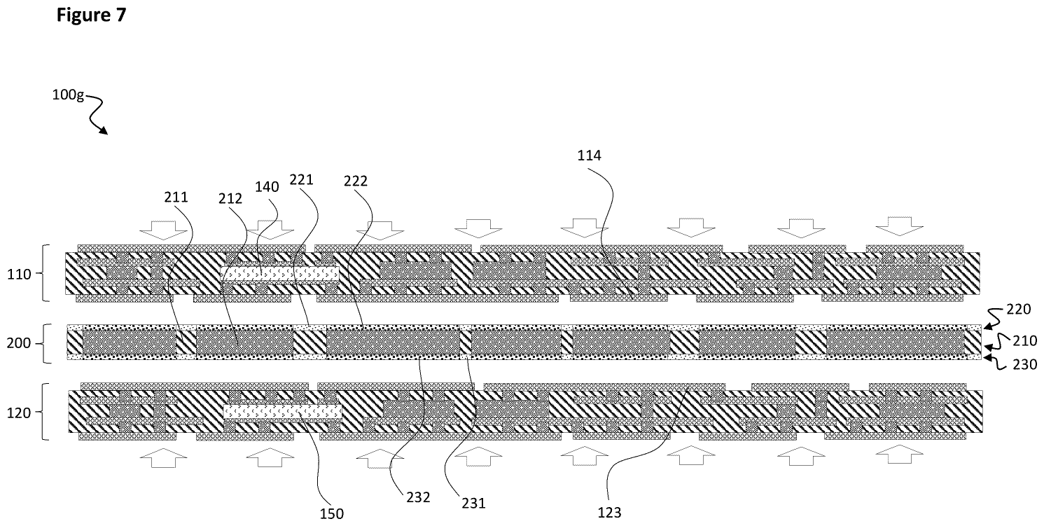

FIG. 7 shows a schematic cross section of a structure 100g or process for a premanufactured hybrid bond sheet 200 with a customized contact pattern. The structure 100g represents an embodiment of the semiconductor power entity 100f shown in FIG. 6 in a layed-up state where the hybrid bond sheet 200 is layed between the first joining member 110 and the second joining member 120.

This process option 5-Customized contact pattern-describes a process where a premanufactured hybrid bond sheet 200 with a customized contact pattern is placed between two laminate layers during the lay-up process step.

In addition to the common features described above with respect to FIG. 6, this hybrid bond sheet embodiment can have a product specific area pattern: The vertical through-connections 212 can be arranged in a pattern that allows optimized clearance and isolation distance. The layout of the bond layers 200 can be designed product specific to achieve the best in thermal and electrical performance. Thus, a specific sheet 200 only suits to connect its corresponding upper and lower PCB layers.

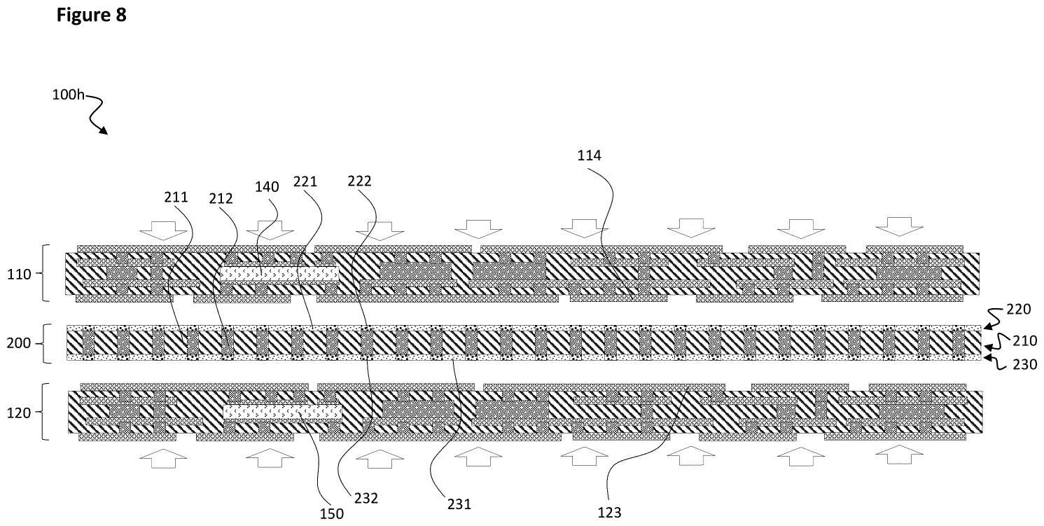

FIG. 8 shows a schematic cross section of a structure 100h or process for a premanufactured hybrid bond sheet 200 with a uniform contact pattern. The structure 100h represents an embodiment of the semiconductor power entity 100f shown in FIG. 6 in a layed-up state where the hybrid bond sheet 200 is layed-up between the first joining member 110 and the second joining member 120.

This process option 6-uniform contact pattern-describes a process where a premanufactured hybrid bond sheet 200 with a uniform contact pattern is placed between two laminate layers during the lay-up process step.

In addition to the common features described above with respect to FIG. 6, this hybrid bond sheet embodiment can have a universal contact scheme: The vertical through-connections 212 can be arranged (but do not have to be) in an array or other repetitive multi-purpose pattern with fixed pitch and defined clearance/conductor cross-section. The purpose thereof is to provide a universal connection scheme for a number of different products/applications with appropriate clearance and no need for alignment. E.g., for all products with the same breakdown voltage/current requirements. Alternatively, the contact scheme can be product specific.

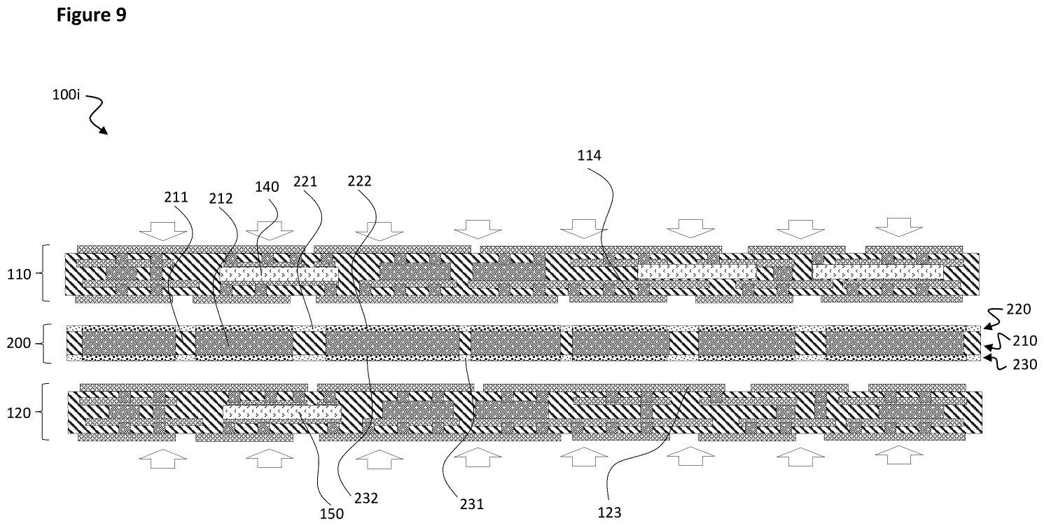

FIG. 9 shows a schematic cross section of a structure 100i or process for a premanufactured hybrid bond sheet 200 supporting a power or logic stacked package configuration. The structure 100i represents an embodiment of the semiconductor power entity 100f shown in FIG. 6 in a layed-up state where the hybrid bond sheet 200 is layed between the first joining member 110 and the second joining member 120.

This process option 7-power or logic stacked package configuration-describes a process where a premanufactured hybrid bond sheet 200 supporting a power or logic stacked package configuration is placed between two laminate layers during the lay-up process step.

Such a stacked configuration with power devices in one layer, e.g., in lower layer 120, and logic devices in another layer, e.g., upper layer 110, allows to manufacture the layers in the technologically and economically best process, for example a logic core layer with smallest lines/spaces and HDI PCB technology, a driver core layer with medium lines/spaces, and a power core layer with large lines/spaces and best dielectric isolation/thermal performance. The different layers 110, 120 are then laminated together by hybrid bonding with or without bond sheets 200. The bond sheet 200 example is shown in FIG. 9.

In addition to the common features described above with respect to FIG. 6, this hybrid bond sheet embodiment can have a vertical integration of logic and power: This embodiment describes how the hybrid bond sheet 200 can be used to connect two or more dissimilar circuit technologies, such as logic and power into one functional vertically integrated system. The circuit technologies can have different requirements with respect to contact density. For example, one can be a HDI PCB, the other one a power PCB with high current copper inlays and embedded power switches.

The vertical connections 212 of the sheet 200 can be of uniform type, arranged in an array, or of the product specific type, e.g., as described above with respect to FIGS. 7 and 8.

Another process option 8-thermoplastic based hybrid bond sheet (not shown in the Figures)—describes a hybrid bond sheet such as the one 200 described above with respect to FIGS. 6 to 9, made of material which becomes soft and flowing at high temperatures, but provides strong adhesion and mechanical support, as well as dielectric isolation and protection from corrosion at normal operation temperature (thermoplastic material). In some embodiments, PCB laminate material is thermosetting, which means that, after curing, it will not remelt, even at higher temperatures (below decomposition temperature) than the curing temperature.

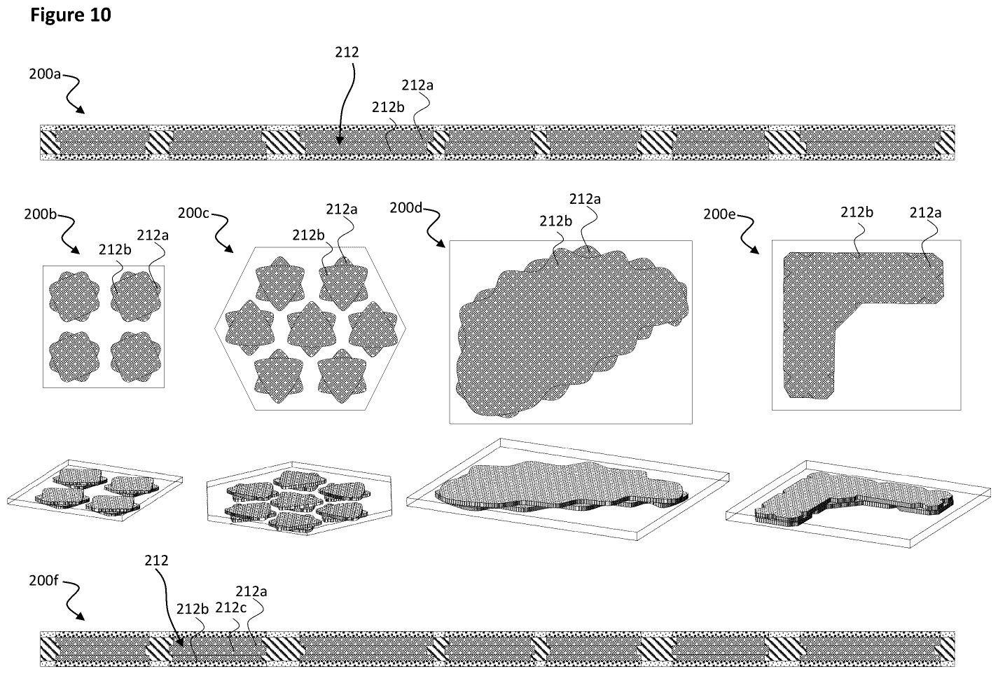

FIG. 10 shows examples of the metallic through connections 212 shown in FIGS. 6 to 9.

The metallic through-connections 212 may include one or more sectioned metallic through-connection. Each one may include two parts as shown for the hybrid bond sheet 200a in the top picture of FIG. 10 or three parts as shown for the hybrid bond sheet 200f in the bottom picture of FIG. 10. It can be understood that more than three parts can be implemented as well.

In the upper picture of FIG. 10, the two parts 212a, 212b may have different diameters.

In the bottom picture of FIG. 10, the three parts 212a, 212b, 212c may have the following characteristics: a middle section 212c of the three sections can be smaller or larger than an upper section 212a and a lower section 212b of the three sections.

For the two parts hybrid bond sheet 200a as shown in the upper picture, different embodiments as shown in the middle pictures of FIG. 10 can be realized.

In one embodiment, the hybrid bond sheet 200b, 200c may include a first part 212a and a second part 212b of different shapes for locking and/or anchoring the sectioned metallic through-connection 212 into the core layer 210. For example, the shape can be a square with rounded corners as shown for the hybrid bond sheet 200b or it can be a triangle with rounded corners as shown for the hybrid bond sheet 200c.

In another embodiment of the hybrid bond sheet 200c, one section 212a can have an equal triangular rounded corner outline, and the other section 212b can have a 60° rotated outline.

In another embodiment of the hybrid bond sheet 200d, the contours of the two sections 212a, 212b can have complementary undulating outlines.

In another embodiment of the hybrid bond sheet 200e, the contours of the two sections 212a, 212b can have notches at mutually exclusive alternating positions at regular intervals of the contour circumference.

While a particular feature or aspect of the embodiments may have been described with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in the detailed description, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the embodiments. The embodiments are intended to cover any adaptations or variations of the specific aspects discussed herein.

Many alternatives, modifications, and variations will be apparent to those skilled in the art in light of the above teachings. Of course, those skilled in the art readily recognize that there are numerous applications of the embodiments beyond those described herein. While implementations and examples described with reference to one or more particular embodiments, those skilled in the art recognize that many changes may be made thereto without departing from the scope of the embodiments. It is therefore to be understood that within the scope of the embodiments and their equivalents, the embodiments may be practiced otherwise than as specifically described herein.

1. A hybrid bond sheet for bonding a first joining member to a second joining member, the hybrid bond sheet comprising:
a core layer having an upper main face and a lower main face opposing the upper main face, the core layer comprising:
a core insulating layer formed between the upper main face and the lower main face; and
one or more metallic through-connections penetrating the core insulating layer from the upper main face to the lower main face;
a first bonding layer for bonding the first joining member, the first bonding layer being formed at the upper main face of the core layer, the first bonding layer comprising:
a first insulating bond layer formed on the core insulating layer; and
a first metal bond layer formed on the one or more metallic through-connections; and
a second bonding layer for bonding the second joining member, the second bonding layer being formed at the lower main face of the core layer, the second bonding layer comprising:
a second insulating bond layer formed on the core insulating layer; and
a second metal bond layer formed on the one or more metallic through-connections; wherein the one or more metallic through-connections and the first and second metal bond layers are configured to form an electrically and thermally conductive connection with the first joining member and the second joining member.

2. The hybrid bond sheet of claim 1, wherein the first joining member and/or the second joining member comprise at least one or a combination of:
a laminate layer,
a mold layer,
a metal-structured laminate or mold layer,
an embedded component layer,
a redistribution metallization layer, and
an interposer layer.

3. The hybrid bond sheet of claim 1, wherein the core insulating layer comprises at least one or a combination of the following:
a printed circuit board laminate,
a mold sheet, an Ajinomoto build-up film (ABF),
a molded interconnect substrate (MIS),
a polymer composite material, and
a polymer sheet material.

4. The hybrid bond sheet of claim 1, wherein the one or more metallic through-connections comprise at least one or a combination of the following components:
metal vias,
metal bars,
metal spacers,
metal studs,
metal bumps, and
metal balls.

5. The hybrid bond sheet of claim 1, wherein the one or more metallic through-connections further comprise:
a first part being formed at the upper main face of the core layer; and
a second part being formed at the lower main face of the core layer.

6. The hybrid bond sheet of claim 1, wherein the one or more metallic through-connections further comprise:
fully metallized non-sectioned or sectioned through-connections of any shape.

7. The hybrid bond sheet of claim 1, wherein the one or more metallic through-connections further comprise:
at least one sectioned metallic through-connection comprising:
a first part; and
a second part of different diameters and/or shapes for locking and/or anchoring the sectioned metallic through-connection into the core layer.

8. The hybrid bond sheet of claim 7, wherein the at least one sectioned metallic through-connection further comprises:
two sections, wherein contours of the two sections have notches at mutually exclusive alternating positions at regular intervals of a contour circumference.

9. The hybrid bond sheet of claim 7, wherein the at least one sectioned metallic through-connection further comprises:
two sections, wherein contours of the two sections have complementary undulating outlines.

10. The hybrid bond sheet of claim 7, wherein the at least one sectioned metallic through-connection further comprises:
two sections, wherein a first section has an equal triangular rounded corner outline, and a second section has a 60° rotated outline.

11. The hybrid bond sheet of claim 7, wherein the at least one sectioned metallic through-connection further comprises:
three sections, wherein a middle section of the three sections is smaller or larger than an upper section and a lower section of the three sections.

12. The hybrid bond sheet of claim 1, wherein the joining members are functional layers and each joining member comprises an outer metallization; wherein one or both of the first metal bond layer and the second metal bond layer form a non-remelting electrical and mechanical connection with the outer metallization of the joining members.

13. The hybrid bond sheet of claim 1, wherein the joining members are functional layers and each joining member comprises an outer metallization; wherein one or both of the first metal bond layer and the second metal bond layer form one of:
a diffusion soldering connection,
a sintering connection or
a nano-hair Velcro bonding connection with the outer metallization of the joining members.

14. The hybrid bond sheet of claim 1, wherein the first insulating bond layer and the second insulating bond layer form an electrically isolating bond connection between the joining members.

15. The hybrid bond sheet of claim 1, wherein the one or more metallic through-connections are arranged in a predetermined pattern that is aligned with a structure of the first joining member and/or the second joining member.

16. The hybrid bond sheet of claim 1, wherein the one or more metallic through-connections are arranged in a predetermined pattern having a uniform structure to support a universal contact scheme for different products and/or applications.

17. The hybrid bond sheet of claim 1, wherein the first insulating bond layer and/or the second insulating bond layer are made of thermosetting material.

18. A semiconductor power entity, comprising:
a first joining member comprising:
a first upper main face;
a first lower main face opposing the first upper main face,
a first metal layer arranged at the first upper main face; and
a second metal layer arranged at the first lower main face;
a second joining member comprising:
a second upper main face;
a second lower main face opposing the second upper main face
a third metal layer arranged at the second upper main face; and
a fourth metal layer arranged at the second lower main face; and
a hybrid bond sheet formed between the first joining member and the second joining member; wherein one or more metallic through-connections and first and second metal bond layers of the hybrid bond sheet form an electrically and thermally conductive connection with the second metal layer and the third metal layer of the first joining member and the second joining member; and a first insulating bond layer and a second insulating bond layer of the hybrid bond sheet form an electrically isolating bond connection between the joining members.

19. The semiconductor power entity of claim 18, wherein the first joining member is embedding a first power semiconductor; and/or wherein the second joining member is embedding a second power semiconductor, and the one or more metallic through-connections and the first and second metal bond layers of the hybrid bond sheet form a direct electrical connection path between the first power semiconductor and the second power semiconductor without a detour via through-hole vias arranged laterally to the two power semiconductors.

20. A method for producing a semiconductor power entity, the method comprising:
providing a first joining member embedding a first power semiconductor, the first joining member having a first upper main face and a first lower main face opposing the first upper main face; wherein a first metal layer is arranged at the first upper main face of the first joining member and a second metal layer is arranged at the first lower main face of the first joining member;
providing a second joining member embedding a second power semiconductor, the second joining member having a second upper main face and a second lower main face opposing the second upper main face; wherein a third metal layer is arranged at the second upper main face of the second joining member and a fourth metal layer is arranged at the second lower main face of the second joining member;
forming a hybrid bond sheet according to claim 1 between the first joining member and the second joining member;
laying-up the first joining member, the second joining member and the hybrid bond sheet;
laminating the layed-up first joining member, second joining member and hybrid bond sheet to a semiconductor power entity, wherein the laminating transforms the one or more metallic through-connections and the first and second metal bond layers of the hybrid bond sheet to form an electrically and thermally conductive connection with the second metal layer and the third metal layer of the first joining member and the second joining member; and
curing the insulating bond layers) of the hybrid bond sheet to form an electrically isolating bond connection between the joining members.
